(19) United States
(12) Patent Application Publication
(10) Pub. No.: US 2025/0372473 A1
(43) Pub. Date: Dec. 4, 2025

(54) PACKAGE AND MANUFACTURING METHOD THEREOF

(71) Applicant: TAIWAN SEMICONDUCTOR MANUFACTURING COMPANY, LTD., Hsinchu (TW)

(72) Inventors: Chih-Hao CHEN, Taipei City (TW); Li-Hui CHENG, New Taipei City (TW); Ying-Ching SHIH, Hsinchu City (TW)

(73) Assignee: TAIWAN SEMICONDUCTOR MANUFACTURING COMPANY, LTD., Hsinchu (TW)

(21) Appl. No.: 18/679,251

(22) Filed: May 30, 2024

(51) Int. Cl. H01L 23/367; H01L 21/50; H01L 23/00; H01L 23/42

(52) U.S. Cl. CPC H01L 23/367; H01L 21/50; H01L 23/42; H01L 23/562; H01L 24/32; H01L 2224/32245

(57) ABSTRACT

A method includes bonding a package component to a substrate; forming a thermal interface material (TIM) over the package component; forming an adhesive layer over the substrate, the adhesive layer laterally surrounding the package component; attaching a lid to the TIM and the adhesive layer, wherein the lid has a recessed portion overlapping the TIM.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-7D, 8, and 9 illustrate schematic views of intermediate stages in the formation of a package in accordance with some embodiments of the present disclosure.

FIGS. 7E and 7F illustrate schematic views of packages in accordance with some embodiments of the present disclosure.

FIGS. 10-17B, 18, and 19 illustrate schematic views of intermediate stages in the formation of a package in accordance with some embodiments of the present disclosure.

FIGS. 17C-17J illustrate schematic views of packages in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In some embodiments, a reduction in the thermal interface material (TIM) layer thickness of a package (e.g., about an 80% decrease) may lead to a high incidence of voids. A non-uniform distribution of the TIM layer thickness (e.g., below 40 micrometers) can result in delamination during reliability testing and thermal performance. Additionally, exceptionally thin TIM layers (e.g., less than 60 micrometers) in scenarios where thermal resistance is less than 3 K·mm²/W, such as in ball grid array (BGA) configurations, must address the challenge of warpage during the ball mount reflow process, which tends to produce voids.

Therefore, the present disclosure in various embodiments provides a lid structure to achieve stable control over void rates when the thickness of the TIM layer is reduced (e.g., by about 80% to less than 60 micrometers of the TIM layer), enabling the reduction in thermal resistance (e.g., 30 to 50% reduction to less than 3 K·mm²/W) in the TIM layer. By employing a lid structure with a recessed portion (e.g., a hump) over the TIM layer, the thickness variation across the package structure can be reduced (e.g., less than 20 micrometers), which in turn enhances power efficiency (e.g., by 2 to 5%) and expands the reliability window. Additionally, the lid structure can be modified to combine a ring structure with a flat lid, which in turn mitigates warpage variations during the ball mount reflow process, ensuring that the TIM layer maintains over, such as 95% coverage, after reflow. Furthermore, a ring structure can be equipped with a bridge structure near the die edge can improve warpage control, further stabilizing the assembly process and enhancing the overall performance and reliability of the package.

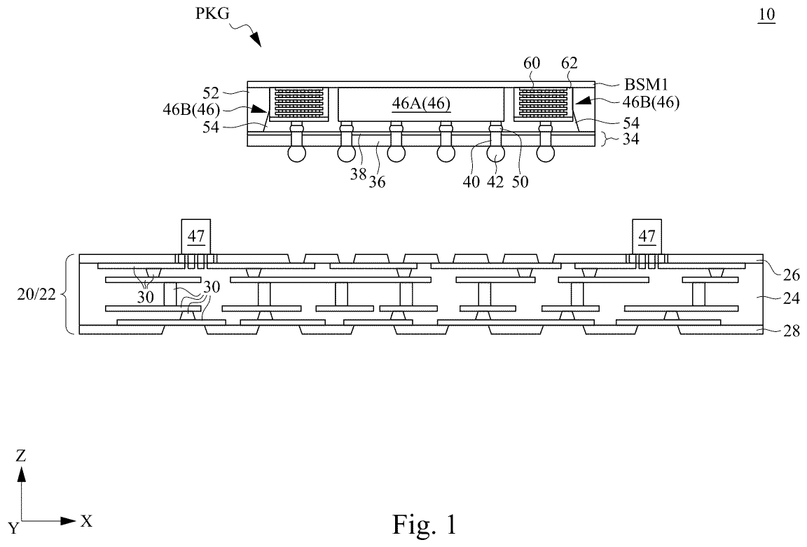

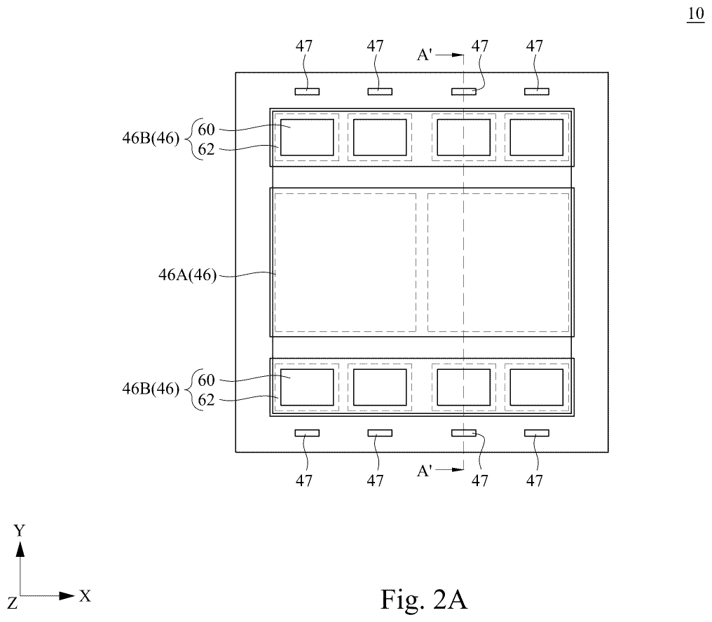

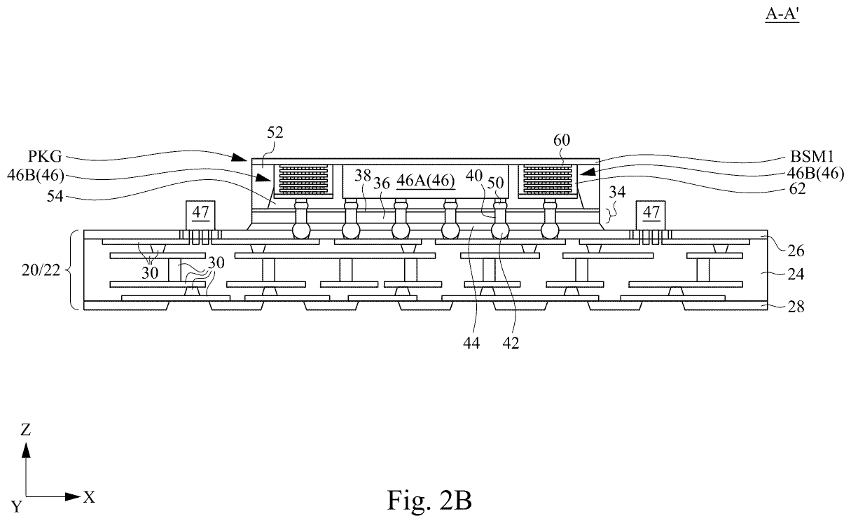

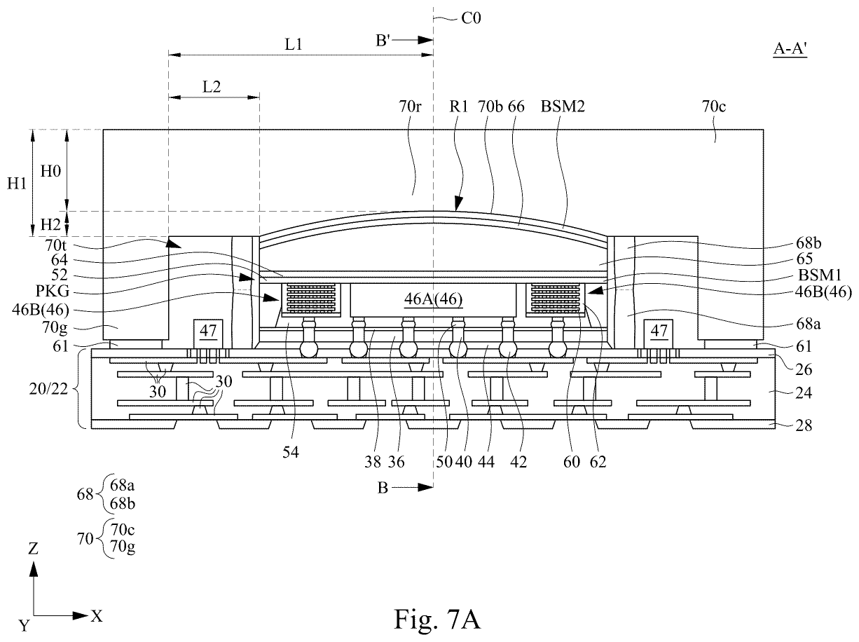

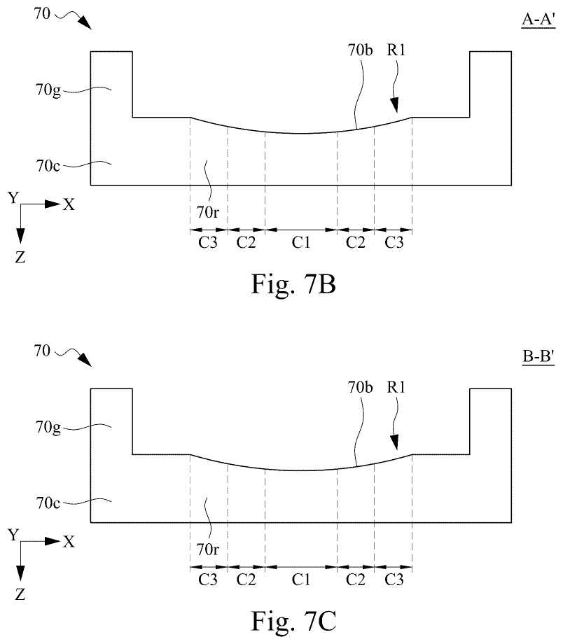

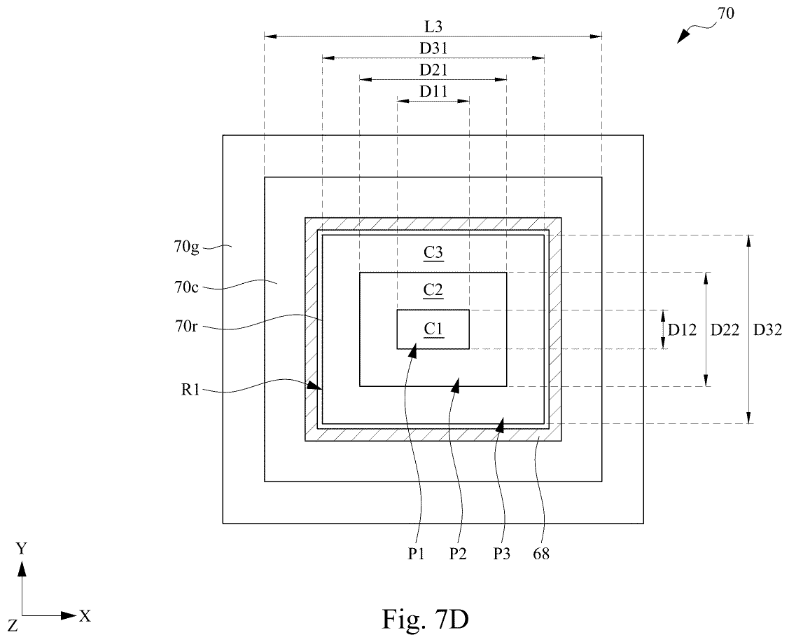

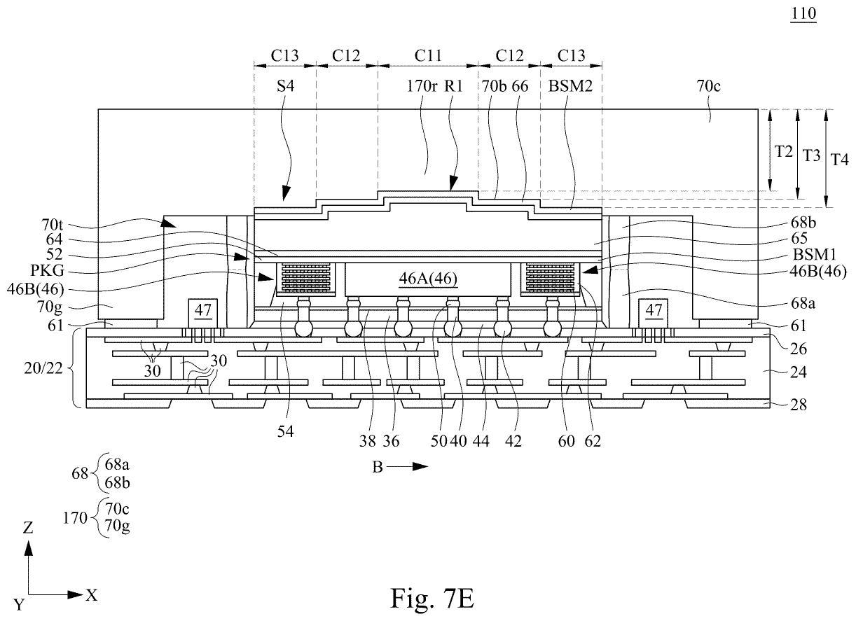

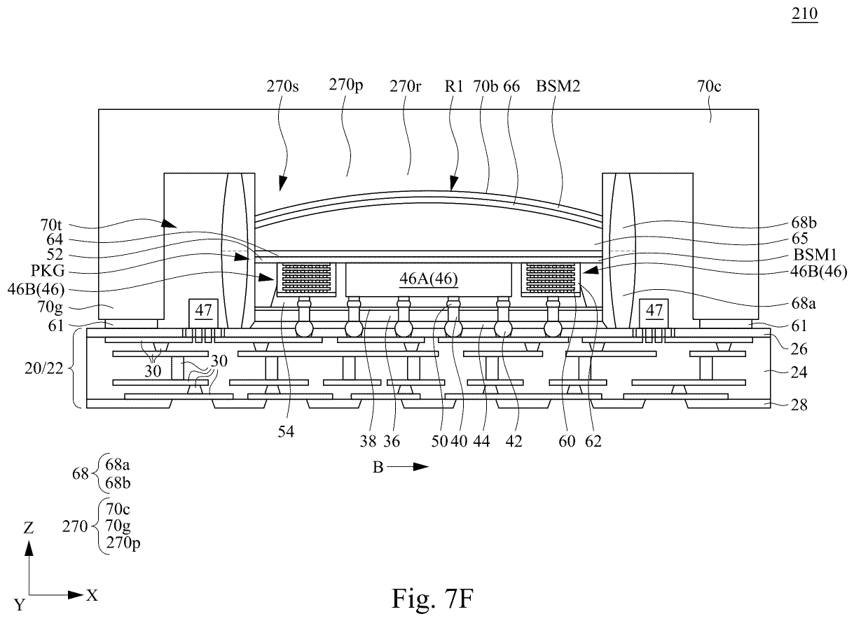

Reference is made to FIGS. 1-7D, 8, and 9. FIGS. 1-7D, 8, and 9 illustrate schematic views of intermediate stages in the formation of a package 10 in accordance with some embodiments of the present disclosure. Specifically, FIG. 2A illustrates a top view of the package 10 in accordance with some embodiments of the present disclosure. FIGS. 1, 2B, 3, 4, 5, 6, 7A, 8, and 9 illustrate cross-sectional views of the package 10 obtained from reference cross-section A-A′ in FIG. 2A in accordance with some embodiments of the present disclosure. FIG. 7B illustrates a cross-sectional view of a lid structure 70 in FIG. 7A in accordance with some embodiments of the present disclosure. FIG. 7C illustrates a cross-sectional view of the lid structure 70 obtained from reference cross-section B-B′ in FIG. 7A in accordance with some embodiments of the present disclosure. FIG. 7D illustrates a top view of the lid structure 70 in FIG. 7A in accordance with some embodiments of the present disclosure. In some embodiments, the package 10 may be a land grid array (LGA) package or a ball grid array (BGA) package. It is understood that additional operations can be provided before, during, and after the processes shown by FIGS. 1-7D, 8, and 9, and some of the operations described below can be replaced or eliminated, for additional embodiments of the method. The order of the operations/processes may be interchangeable.

Reference is made to FIGS. 1-2B. In FIG. 1, a package component 20 can be provided. The package component 20 can includes a plurality of package components 22 therein. In accordance with some embodiments, the package component 20 can be a package substrate strip, which includes a plurality of package substrates 22 therein. The package substrates 22 may be cored package substrates including cores, or may be core-less package substrates that do not have cores therein. In accordance with alternative embodiments, the package component 20 may be of another type such as an interposer wafer, a printed circuit board, a reconstructed wafer, or the like. The package component 20 may be free from (or may include) active devices such as transistors and diodes therein. Package component 20 may also be free from (or may include) passive devices such as capacitors, inductors, resistors, or the like therein.

In accordance with some embodiments of the present disclosure, the package component 20 includes a plurality of dielectric layers, which may include dielectric layers 24, a dielectric layer 26 over the dielectric layers 24, and a dielectric layer 28 under the dielectric layers 24. In accordance with some embodiments, the dielectric layers 26 and 28 may be formed of dry films such as Ajinomoto Build-up Films (ABFs). Alternatively, the dielectric layers 26 and 28 may be formed of or comprise polybenzoxazole (PBO), polyimide, benzocyclobutene (BCB), or the like, which may be coated in a flowable form and then cured. The dielectric layers 24, when being in a core, may be formed of epoxy, resin, glass fiber, prepreg (which comprises epoxy, resin, and/or glass fiber), glass, molding compound, plastic, combinations thereof, and/or multi-layers thereof. In accordance with alternative embodiments, the dielectric layers 24 may be formed of polymers such as PBO, polyimide, BCB, or the like. Redistribution lines 30, which include metal lines/pads and vias, are formed in the dielectric layers 24. The redistribution lines 30 can be interconnected to form through-connections in the package component 20. In accordance with some embodiments, when the package component 20 is not rigid enough to support itself and the overlying structure, a first carrier (not shown) can be provided to support the package component 20. In accordance with alternative embodiments, the package component 20 is thick and rigid (for example, when being a reconstructed wafer), and is able to support the structure formed thereon. Accordingly, the first carrier may not be used. The first carrier, when used, may be a glass carrier, an organic carrier, or the like. In accordance with alternative embodiments, the package component 20 can be pre-formed. In accordance with alternative embodiments, the package component 20 is built layer-by-layer over the first carrier.

Further referring to FIG. 1, package structures PKG can be placed on the package component 20. Although one package structure PKG is illustrated, a plurality of package structures PKG can be placed in this process, each being placed over a corresponding one of the package components 22. In some embodiments, the package structure PKG can be interchangeable referred to as package component or a package. The package structures PKG include device dies therein, and may include other package components such as interposers, packages, die stacks, or the like. In accordance with some embodiments, the package structures PKG can include a package component 34 and package components 46A and 46B. In accordance with some embodiments, the package components 34 can be interposers, which can include substrates 36 and the corresponding dielectric layers 38. Accordingly, the package components 34 may also be referred to as interposers, while the package components 34 may also be of other types. The structure of the package components 34 is illustrated schematically, and the details such as the plurality of dielectric layers on the top side and bottom side of substrate 36, metal lines and vias, metal pads, or the like, are not shown. Through-substrate vias 40 can penetrate through substrate 36. The through-substrate vias 40 can be used to interconnect the conductive features on the top side and the bottom side of substrate 36 to each other. Solder regions 42 may be underlying and joined to interposers, and are used to bond the package components 34 to package component 20. Other bonding schemes such as metal-to-metal direct bonding, hybrid bonding, or the like, may also be used for bonding the package components 34 to the package component 20.

In accordance with some embodiments, the package components 46A and 46B are bonded to the respective underlying package component 34. FIG. 1 illustrates a cross-section wherein one package component 46A and two package components 46B are visible, and are bonded to the same package component 34. The package components 46A and 46B can be different types of package components, and are collectively referred to as package components 46. Each of the package components 46 may be a device die, a package with a device die(s) packaged therein, a System-on-Chip (SoC) die including a plurality of integrated circuits (or device dies) integrated as a system, or the like. The device dies in package components 46 may be or may comprise logic dies, memory dies, input-output dies, Integrated Passive Devices (IPDs), or the like, or combinations thereof. For example, the logic device dies in package components 46 may be Central Processing Unit (CPU) dies, Graphic Processing Unit (GPU) dies, mobile application dies, Micro Control Unit (MCU) dies, BaseBand (BB) dies, Application processor (AP) dies, or the like. The memory dies in package components 46 may include Static Random Access Memory (SRAM) dies, Dynamic Random Access Memory (DRAM) dies, or the like. The device dies in package components 46 may include semiconductor substrates and interconnect structures.

In the subsequent discussion in accordance with some example embodiments, the package components 46A can be referred to as device dies, which may be SoC dies in accordance with some embodiments. The package components 46B may be memory stacks such as High-Performance Memory (HBM) stacks. The package components 46B may include memory dies 60 forming a die stack, and an encapsulant 62 (such as a molding compound) encapsulating memory dies 60 therein. When viewed from top (see FIG. 2A), the encapsulant 62 may form a ring encircling the memory dies 60, and may also extend into the gaps between the memory dies 60.

Further referring back to FIG. 1, the package components 46 may be bonded to the underlying package component 34, for example, through solder regions 50. Underfills 54 can be dispensed between the package components 46 and the underlying package component 34. In some embodiments, the material of the underfill 54 can an insulating material and includes a resin (e.g., epoxy resin), a filler material, a stress release agent (SRA), an adhesion promoter, other material, or a combination thereof. In some embodiments, the underfill 54 is optional. In accordance with some embodiments, the package structures PKG can be formed through a Chip-on-Wafer (CoW) bonding process, wherein the package components 46, which are discrete chips/packages, are bonded to the package components 34 that are in an unsawed wafer to form a reconstructed wafer.

After the dispensing of the underfills 54, an encapsulant such as a molding compound 52 may be applied, followed by a planarization process on the molding compound 52 to level its top surface with the top surfaces of the package components 46. In some embodiments, the molding compound 52 can be a molding compound, a molding underfill, a resin (such as epoxy resin, phenolic resin), or the like. In some alternative embodiments, the material of the molding compound 52 can include silicon oxide (SiOₓ, where x>0), silicon oxynitride (SiOₓN_{y}, where x>0 and y>0), silicon nitride (SiNₓ, where x>0), or other suitable dielectric material. In some embodiments, the molding compound 52 includes fillers. The fillers may be particles made of silica, aluminum dioxide, or the like. In some embodiments, the molding compound 52 is formed by a molding process, an injection process, a film deposition process, a combination thereof, or the like. The molding process includes, for example, a transfer molding process, a compression molding process, or the like. The film deposition process includes, for example, CVD, HDPCVD, PECVD, ALD, or combinations thereof.

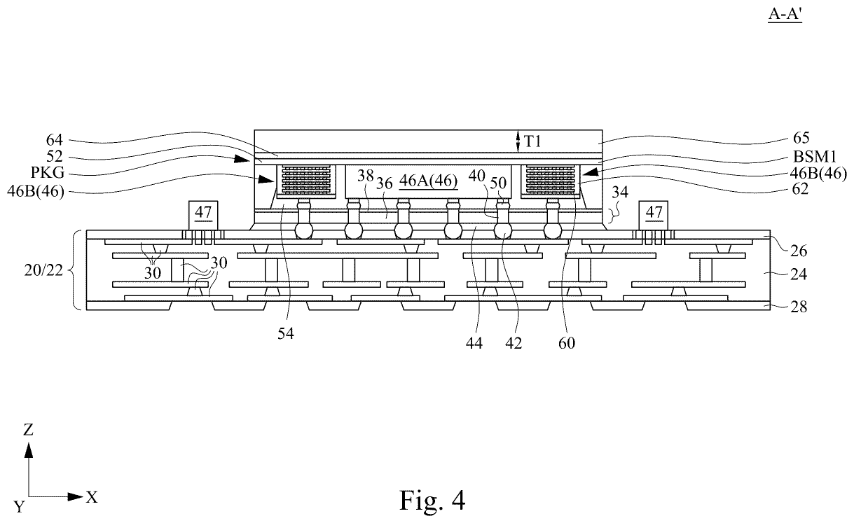

Further referring back to FIG. 1, a conductive layer BSM1 can be formed on the package components 46A and 46B and the molding compound 52, and thus a reconstructed wafer can be thus formed. The conductive layer BSM1 can be in physical contact with the top surfaces of the package components 46A, the top surfaces of the package components 46B, the top surface of the molding compound 52, and the top surface of the molding compound 54. In some embodiments, the conductive layer BSM1 can include multiple metal layers, including an adhesion layer to ensure strong bond formation, a diffusion barrier layer to prevent unwanted material migration, and an anti-oxidation layer (e.g., gold) to protect against environmental damage. However, the disclosure is not limited to. In some embodiments, the material of the conductive layer BSM1 can include metal, such as aluminum (Al), titanium (Ti), nickel (Ni), vanadium (V), tantalum (Ta), silver (Ag), and gold (Au). The thickness of the conductive layer BSM1 can be in a range from about 10 angstroms (Å) to 10,000 Å, such as about 10, 100, 1000, or 10,000 Å, allowing for flexibility in application. In some embodiments, the conductive layer BSM1 can formed by sputtering, electroplating, deposition, or dispensing process. It is noted that the conductive layer BSM1 can be utilized to promote adhesion between the subsequently formed metallic thermal interface material (TIM) layer (e.g., TIM layer 65 as shown in FIG. 4) and the package structure PKG, and can be changeable referred to as a backside metallization or a backside metal layer.

The reconstructed wafer can be sawed apart to form the discrete package structures PKG, which can be bonded to package component 20. A singulation process is performed on the molding compound 52 and the package components 34 to obtain the package structure PKG illustrated in FIG. 1. Although only one package structure PKG is presented in FIG. 1 for illustrative purposes, those skilled in the art can understand that after the singulation process is performed, a plurality of package structures PKG can be obtained. In some embodiments, the singulation process can include dicing with a rotation blade and/or a laser beam. In other words, the singulation process can include a laser cutting process, a mechanical cutting process, a laser grooving process, other suitable processes, or a combination thereof. In some embodiments, since the package component 34 is in wafer form, the package structure PKG is considered to be formed by a chip-on-wafer process, and also the package structure PKG is referred to as a chip-on-wafer package.

As shown in FIGS. 2A and 2B, after the placement of the package structures PKG onto the package component 20, the solder regions 42 can be reflowed, and an underfill 44 (see FIG. 2B) may be dispensed to a gap between the package structures PKG and the package component 20. In some embodiments, the material of the underfill 44 is an insulating material and includes a resin (e.g., epoxy resin), a filler material, a stress release agent (SRA), an adhesion promoter, other material, or a combination thereof. In some embodiments, the underfill 44 can be optional. There may be other package components such as surface mount devices (SMDs) 47 bonding to the package component 20. In accordance with some embodiments, the surface mount devices 47 can be discrete capacitors, discrete inductors, discrete resistors, or the like. In some embodiments, no active devices such as transistors are formed in the surface mount devices 47, and the surface mount devices 47 can be changeable referred to as Independent Passive Devices (IPDs). As shown in FIG. 2A, the package structure PKG may include one or more device die(s) 46A, and a plurality of memory stacks 46B. Each of the memory stacks 46B may include stacked memory dies 60 and encapsulant 62 molding (and encircling) memory dies 60. The encapsulant (for example, a molding compound) 52 can fill the spaces between neighboring the package components 46. The surface mount devices 47 may be bonded to the peripheral region of the package component 22.

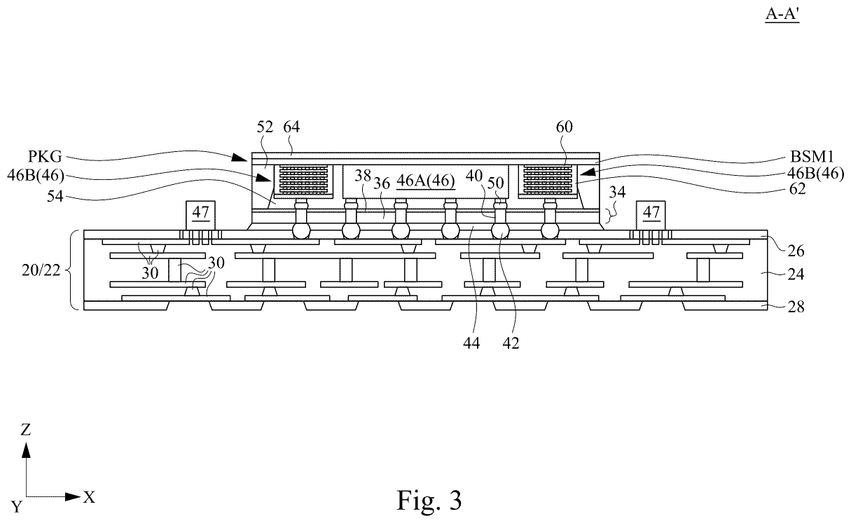

Reference is made to FIG. 3. A flux 64 may be applied onto the conductive layer BSM1 for better adhesion. For example, before the metallic TIM layer 65 (see FIG. 4) is placed on the conductive layer BSM1, the flux 64 can be formed over the package structure PKG. In some embodiments, the formation of the flux 64 can include performing a jetting process or a dispensing process. In some embodiments, the flux can be a solder flux. In some embodiments, the material of the flux 64 can include rosin or acids.

Reference is made to FIG. 4. The TIM layer 65 can be formed on the flux 64. In some embodiments, the TIM layer 65 can be in sheet type. In some embodiments, the TIM layer 65 can be formed on the flux 64 through a pick-and-place process. In some embodiments, the material of the TIM layer 65 can be soldered type material. In some embodiments, the TIM layer 65 can be formed by purely metallic materials and can be interchangeable referred to as a metal thermal interface material. In some embodiments, the TIM layer 65 can be free of organic material and polymeric material. In some embodiments, the material of the TIM layer 65 includes a metallic material, such as indium, copper, tin, Ag, or an alloy thereof. In some embodiments, the thermal conductivity of the TIM layer 65 ranges from about 10 W/(m·K) to about 90 W/(m·K). In some embodiments, the Young's modulus of the TIM layer 65 ranges from about 5 GPa to about 70 GPa. In some embodiments, the TIM layer 65 can have a thickness T1 in a range less than about 100 micrometers, such as about 5, 10, 20, 30, 40, 50, 60, 70, 80, 90, or 100 micrometers.

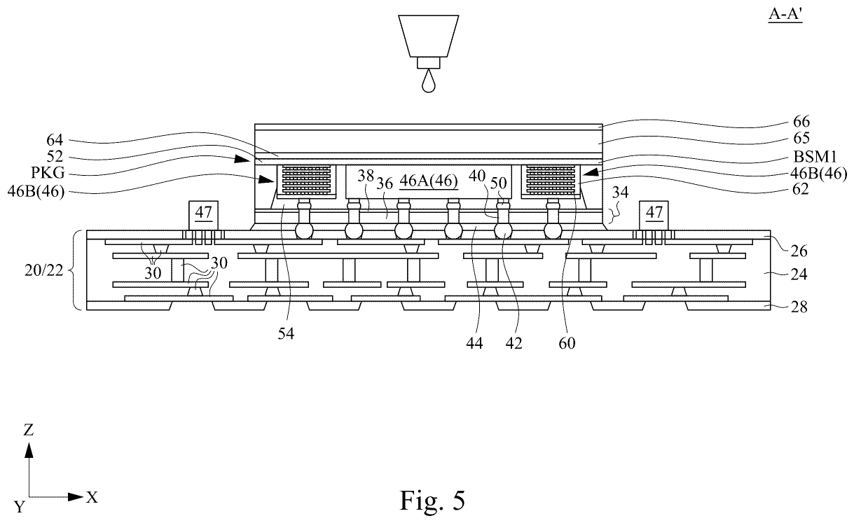

Reference is made to FIG. 5. A flux 66 may be applied onto the TIM layer 65 for better adhesion. For example, before a lid structure 70 (see FIG. 7A) is placed on the TIM layer 65, the flux 66 can be formed over the TIM layer 65. In some embodiments, the formation of the flux 66 can include performing a jetting process or a dispensing process. In some embodiments, the flux can be a solder flux. In some embodiments, the material of the flux 66 can include rosin or acids.

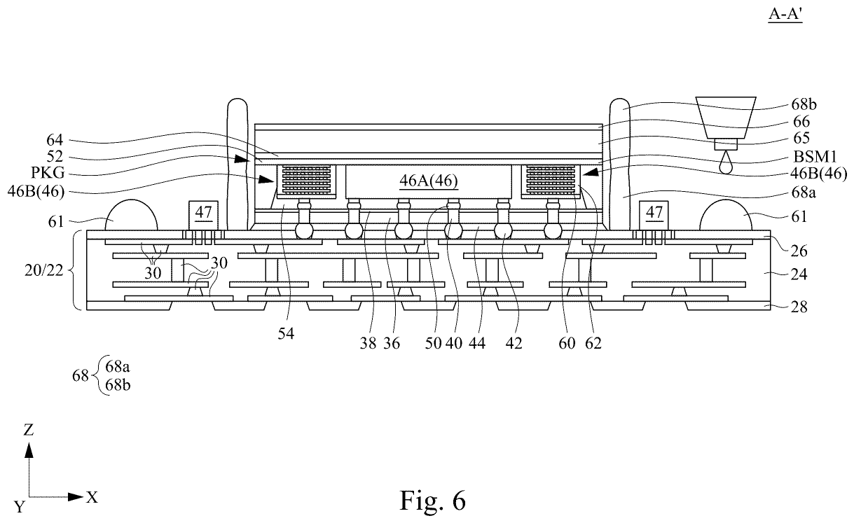

Reference is made to FIG. 6. An adhesive structure 61 and an adhesive structure 68 can be formed over the package component 20. Specifically, the adhesive structure 61 can be formed near edges of the package component 20 to surround/encircle the package structure PKG. In some embodiments, the adhesive structure 61 can have a ring-like shape in the plane view. In some embodiments, the pattern of the adhesive structure 61 may be designed based on the various design. For example, the adhesive structure 61 may have a linear shape, L shape, U shape, dot shape, etc. In some embodiments, the shape of the adhesive structure 61 can depend on the shape of the package component 20. For example, when the package structure PKG can be in panel form (i.e., having a rectangular or squared top view), the adhesive structure 61 can exhibit a rectangular or squared ring-like shape from the top view. In some embodiments, the adhesive structure 61 can be interchangeable referred to as an adhesive layer.

The adhesive structure 68 can be formed near the package structure PKG to surround/encircle the TIM layer 65 and spaced apart from the adhesive structure 61. On the other hand, the adhesive structure 61 can surround/encircle the adhesive structure 68. In some embodiments, the adhesive structure 68 can have a top in a position higher than a top surface of the package structure. In some embodiments, the adhesive structure 68 can have a ring-like shape in the plane view. In some embodiments, the adhesive structure 68 can be a layered structure having a number of layers vertical stacked with each other, and the number of layers is greater than 2, such as 2, 3, 4, or 5. By way of example and not limitation, the adhesive structure 68 can be a two-layer ring structure having a first layer 68a and a second layer 68b over and in contact with a top portion of the first layer 68a. In some embodiments, the first layer 68a of the adhesive structure 68 can be interchangeable referred to as a first adhesive layer, and the second layer 68b of the adhesive structure 68 can be interchangeable referred to as a second adhesive layer. In some embodiments, the pattern of the adhesive structure 68 may be designed based on the various design. For example, the adhesive structure 68 may have a linear shape, L shape, U shape, dot shape, etc. In some embodiments, the shape of the adhesive structure 68 can depend on the shape of the package component 20. For example, when the package component 20 can be in panel form (i.e., having a rectangular or squared top view), the adhesive structure 68 can exhibit a rectangular or squared ring-like shape from the top view.

In some embodiments, the adhesive structures 61 and 68 can be applied onto the package component 20 through a dispensing process, a spin-coating process, or the like. The adhesive structures 61 and the first layer 68a of adhesive structure 68 may be formed first, and then the second layer 68b of the adhesive structure 68 may be formed on the first layer 68a of the adhesive structure 68. The formation of adhesive structures 68 and 61 within semiconductor packaging can be flexible, accommodating different assembly processes. In some embodiments, the adhesive structure 68 can be formed after the adhesive structure 61. In this sequence, the broader boundary adhesive structure 61 can be applied first, circling the perimeter of the package component. This initial application can provide a foundational layer that secures the outer edges of the assembly. Following this, the more centrally located adhesive structure 68 can be applied, surrounding the TIM layer 65 and other internal components. In some embodiments, the adhesive structure 68 can be formed before adhesive structure 61. In some embodiments, the adhesive structure 68 can have a width narrower than a width of the adhesive structure 61.

In some embodiments, the adhesive structure 61/68 can have a thermal conductivity greater than about 0 W/m·K to 5 W/m·K. In some embodiments, the adhesive structure 61/68 can include a silicon-based material, an acrylic-base material, an epoxy-based polymer, or combinations thereof. However, the disclosure is not limited to. In some alternative embodiments, other polymeric materials having adhering property may be utilized as the adhesive structure 61/68. In some embodiments, the adhesive structure 68 can be made of a same material as the adhesive structure 61. In some embodiments, the adhesive structure 68 can be made of a different material than the adhesive structure 61. In some embodiments, the first layer 68a of the adhesive structure 68 can be made of a different material than the second layer 68b of the adhesive structure 61, and thus the first and second layers 68a and 68b may form a distinguishable interface therebetween. In some embodiments, the first layer 68a of the adhesive structure 68 can be made of a same material as the second layer 68b of the adhesive structure 61, and thus the first and second layers 68a and 68b may not form a distinguishable interface therebetween.

Reference is made to FIGS. 7A-7D. A lid structure 70 can be placed over the TIM layer 65 and adhesive structures 61 and 68, such that the package structure PKG can be located between the lid structure 70 and the package component 20. In some embodiments, the lid structure 70 can serve for heat dissipation. In other words, the heat generated during operation of the package structure PKG may be dissipated through the path created by the lid structure 70. In some embodiments, the lid structure 70 can be made of metal, plastic, ceramics, or the like. The metal for the lid structure 70 includes, but is not limited to, aluminum, copper, stainless steel, solder, gold, nickel, molybdenum, alloy42, Fe, Ag, NiFe or NiFeCr. In some embodiments, the thermal conductivity of the lid structure 70 ranges from about 80 W/(m·K) to about 450 W/(m·K). In some embodiments, the Young's modulus of the lid structure 70 ranges from about 50 GPa to about 200 GPa.

In some embodiments, the lid structure 70 can include a central cover portion 70c and a leg portion 70g extending around its periphery to form a cavity 70t therein. In some embodiments, the central cover portion 70c can be a flat configuration. In some embodiments, the leg portion 70g can be interchangeable referred to as a foot portion, a protruding portion, or a peripheral region. In some embodiments, an extending direction of the cover portion 70c can be perpendicular to an extending direction of the leg portion 70g. From another point of view, in some embodiments, the cover portion 70c extends along the direction X and the direction Y, and the leg portion 70g extends along the direction Z. In some embodiments, the cover portion 70c and the leg portion 70g can be integrally formed. In some embodiments, the leg portion 70g of the lid structure 70 can be attached to the package component 20 through the adhesive structure 61 during the curing process. In some embodiments, the shape of the leg portion 70g can depend on the shape of the package component 20. For example, when the package component 20 can be in panel form (i.e., having a rectangular or squared top view), the leg portion 70g can exhibit a rectangular or squared ring-like shape from the top view.

In some embodiments, a reduction in thickness of the TIM layer 65, such as by as much as 80% to levels thinner than about 60 micrometers, can improve in thermal performance and device compactness. A thinner TIM layer 65 can improve thermal conductivity between the package structure PKG and the lid structure 70 by minimizing the thermal resistance of the interface, which in turn allows for more efficient cooling, leading to better overall device performance. However, a thinner TIM layer may more susceptible to uneven application or spreading, making it difficult to achieve a consistent layer between the lid structure 70 and the package structure PKG. A disparate thickness distribution (i.e., non-uniform thickness) across the TIM layer 65 (e.g., variation exceeds about 40 μm) may tend to facilitate delamination under reliability testing conditions and lead to diminished thermal performance. In some embodiments, the thickness of the TIM layer 65, positioned between the lid structure 70 and the package structure PKG, can be interchangeable referred to as a thermal-interface-material between-lid-thickness (BLT).

In some embodiments, when the thickness of the TIM layer 65 falls below, such as 60 micrometers, and it possesses thermal conductivity, such as under 3 K·mm²/W, in a ball grid array (BGA) setup, the warping effect experienced during the ball mount reflow process may need to be addressed. This warping can lead to the formation of voids, impacting the reliability and thermal efficiency of the package structure PKG. In some embodiments, the voids can be generated due to outgassing of solvents or fluxes. The reflow soldering process, which may involve the melting and solidification of solder to form electrical and mechanical connections, can intensify void formation in thinner TIM layer due to thermal cycles. These thermal cycles may trigger outgassing from the TIM layer 65, thereby heightening the risk of voids. The voids can act as thermal insulators due to the low thermal conductivity of air, reducing the overall effectiveness of heat dissipation from the package structure PKG to the lid structure 70.

The lid structure 70 can address non-uniform thickness distribution across the TIM layer 65, which can lead to delamination and impaired thermal performance. The lid structure 70 can have a recessed portion 70r located on the central cover portion 70c to form a recess R1. In some embodiments, the recessed portion 70r can be interchangeable referred to as a hump. The range of the recessed portion 70r can be tailored to match the size of the package structure PKG, ensuring precise alignment. Surrounding the recessed portion 70r, a footprint of the adhesive structure 68 can form a non-overlapping boundary. A footprint of the recessed portion 70r can overlap a footprint of the package structure PKG and a footprint of the TIM layer 65, enhancing thermal contact efficiency, and a footprint of the recessed portion 70r of the lid structure 70 does not overlap a footprint of the adhesive structure 68 on the package component 20.

Specifically, a concave bottom surface 70b of the recessed portion 70r can feature an architectural gradient, recessed away from the leg portion 70g and including multiple areas (e.g., greater than two distinct areas, such as 2, 3, 4, 5, 6, 7, 8, 9, 10 areas), such as a central area C1 (see FIGS. 7B-7D), a transition area C2 (see FIGS. 7B-7D) encircling the central area C1, and a peripheral area C3 (see FIGS. 7B-7D) encircling the transition area C2, allowing for a continuous recess from the peripheral area C3 towards the central area C1, deepening as it approaches the center. Consequently, the recessed portion 70r can create a zone with varying thickness levels that can mitigate the issues associated with disparate thickness distribution in the TIM layer 65. The central area C1 can exhibit the thinnest area in the recessed portion 70r which gradually thickens moving towards the peripheral area C3. After attaching the lid to the TIM layer 65, a top surface of the TIM layer 65 can be conform to the concave bottom surface 70b of the lid structure 70. This graded recessed design may ensure a more uniform application of the TIM layer 65, minimizing the risk of voids and delamination while optimizing thermal conductivity. By addressing the thickness variability, the lid structure 70 can enhance the overall reliability and thermal efficiency of the semiconductor package. Thereafter, the nearly complete coverage of the TIM layer 65 over the package structure PKG can be achieved. In some embodiments, the coverage can be greater than about 95%, such as about 95, 96, 97, 98, 99, 99.5, or 99.9%. In some embodiments, the thicknesses of the recessed portion 70r in the central area C1, transition area C2, and peripheral area C3 are constant values, respectively, so that the bottom surface 70b of the recessed portion 70r can present a stepped structure. In some embodiments, the transition area C2 and/or peripheral area C3 can be interchangeable referred to as a ring-shaped region.

Therefore, the lid structure 70 can facilitate consistent control over the rate of void formation, even when the thickness of the TIM layer 65 is reduced by about 80%, resulting in a thickness of less than, such as 60 micrometers. Consequently, the lid structure 70 can contribute to an additional thermal resistance (TR) reduction of 30 to, such as about 50%, achieving a TR of less than, such as about 3 K·mm²/W for the TIM layer 65. Additionally, the use of the lid structure 70 with the recessed portion 70r can enable the reduction of thickness variation in the TIM layer 65 to less than, such as about 20 micrometers. As a result, the package 10 can have a 2 to 5% increase in power performance, alongside an expanded reliability margin.

As shown in FIG. 7A, the central cover portion 70c of the lid structure 70 can have a minimum vertical dimension H0, a maximum vertical dimension H1, and the recess R1 can have a maximum vertical dimension H2 less than the maximum vertical dimension H1. In some embodiments, a ratio between the minimum vertical dimension H0 and the maximum vertical dimension H1 can be in a range from about 90 to 99.5, such as about 90, 91, 92, 93, 94, 95, 96, 97, 98, 99, or 99.5%. A distance L1 from a central C0 to the leg portion 70g can be greater than a distance L2 from the TIM layer 65 to the leg portion 70g. In some embodiments, the shape of the recessed portion 70r can depend on the shape of the package structure PKG. For example, when the package structure PKG has a rectangular top view, the recessed portion 70r can exhibit a rectangular top view corresponding to the package structure PKG.

As shown in FIG. 7D, the peripheral area C3 of the recessed portion 70r can have a first rectangular ring-like profile P3, the transition area C2 of the recessed portion 70r can have a second rectangular ring-like profile P2, and the central area C1 can have a rectangular profile P1 from the top view. In some embodiments, the first rectangular ring-like profile P1 of the central area C1 can have a dimension D11 extending in X-direction and a dimension D12 extending in Y-direction. The second rectangular ring-like profile P2 of the transition area C2 can have a dimension D21 extending in X-direction and a dimension D22 extending in Y-direction. The rectangular profile P3 of the peripheral area C3 can have a dimension D31 extending in X-direction and a dimension D32 extending in Y-direction. By way of example and not limitation, a ratio between the dimension D11, the dimension D21, and the dimension D31 can be about 0.3:0.6:1, and a ratio between the dimension D12, the dimension D22, and the dimension D32 can be about 0.3:0.6:1. In some embodiments, opposite two portions of the leg portion 70g can have a distance L3 therebetween, and a ratio between the dimension D31/D32 and the distance L3 can be in a range from about 0.6 to 0.9, such as about 0.6, 0.65, 0.7, 0.75, 0.8, 0.85, or 0.9.

In some embodiments, prior to the attachment of the lid structure 70, a conductive layer BSM2 can be formed on the recessed portion 70r of the central cover portion 70c of the lid structure 70. It is noted that the conductive layer BSM2 can be utilized to promote adhesion between the metallic TIM layer 65 and the lid structure 70, and can be referred to as a backside metallization or a backside metal layer. In some embodiments, the material of the conductive layer BSM2 can be the same as the material of the conductive layer BSM1. In alternative some embodiments, the material of the conductive layer BSM2 can be different from the material of the conductive layer BSM1. In some embodiments, the conductive layer BSM2 can be formed on the lid structure 70 through a plating, sputtering or dispensing process. In some embodiments, the material of the conductive layer BSM2 can include metal, such as Al, Ti, Ni, V, Au, Ag or Cu. In some embodiments, the conductive layer BSM2 can be an Au plated heat sink. That is, the back-side of the lid structure 70 can be coated with gold (Au) to improve thermal conductivity and resist oxidation. In some embodiments, the conductive layer BSM2 can be interchangeable referred to as an aurum layer. In some alternative embodiments, there is no conductive layer BSM2 formed on the lid structure 70.

In some embodiments, after the conductive layer BSM2 is formed on the lid structure 70, the lid structure 70 and the conductive layer BSM2 can be placed above the TIM layer 65 and the adhesive structures 61 and 68, such that the lid structure 70 can be in physical contact with the top surfaces of the adhesive structures 61 and 68.

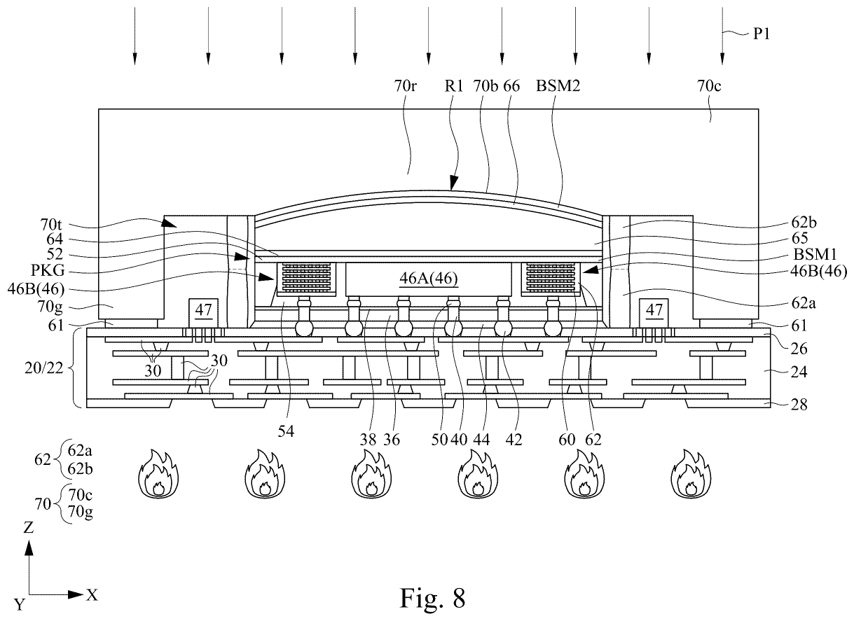

Reference is made to FIG. 8. The lid structure 70 and the conductive layer BSM2 are pressed against the TIM layer 65 and the adhesive structures 61 and 68. In some embodiments, pressing the lid structure 70 and the conductive layer BSM2 against the TIM layer 65 and the adhesive structures 61 and 68 can include performing a heat clamping process P1, wherein the process temperature of the heat clamping process ranges from about 60° C. to about 300° C. In some embodiments, the clamping process P1 can be interchangeable referred to as a heat clamp process. Subsequently, a curing process can be performed on the adhesive structures 61 and 68, such that the lid structure 70 can be attached to the package component 20 through the adhesive structures 61 and 68. In detail, the curing process can be performed on the adhesive structures 61 and 68 to securely fix the lid structure 70 onto the package component 20. In some embodiments, the process temperature of the curing process ranges from about 60° C. to about 300° C. However, the disclosure is not limited to. In some embodiments, during the curing process, the lid structure 70 can be attached to the package structure PKG through the TIM layer 65. That is to say, in such embodiments, during the curing process, there is a good physical and metallurgical connection of the lid structure 70 to the package structure PKG.

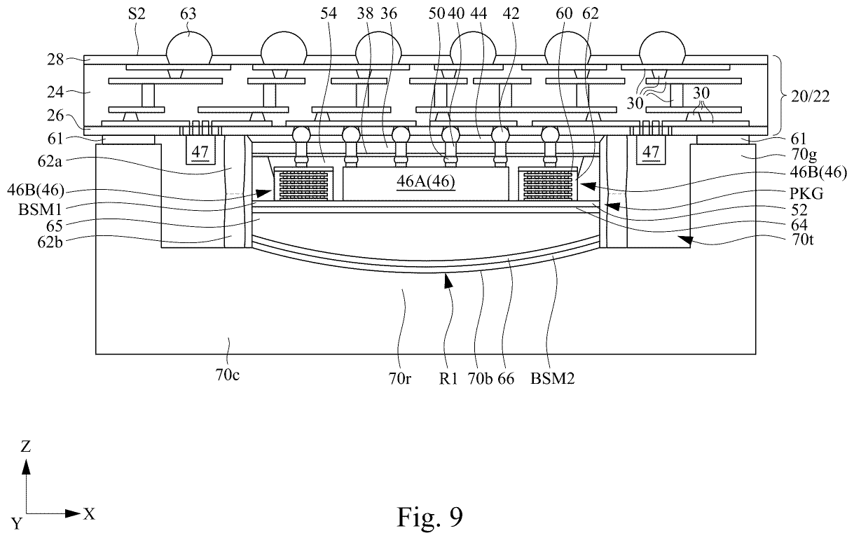

Reference is made to FIG. 9. A plurality of conductive terminals 63 can be formed on the surface S2 of the package component 20. In some embodiments, the conductive terminals 63 are solder balls, ball grid array (BGA) balls, or the like. In some embodiments, the conductive terminals 63 are made of a conductive material with low resistivity, such as Sn, Pb, Ag, Cu, Ni, Bi, or an alloy thereof. In some embodiments, the conductive terminals 63 can be in physical contact with the redistribution lines 30 (or routing patterns) exposed at the surface S2 of the package component 20. In some embodiments, the conductive terminals 63 can be used to physically and electrically connect the package component 20 to other devices, packages, connecting components, and the like. That is to say, the conductive terminals 63 can be used for providing physical and/or electrical connection to external components. As shown in FIG. 9, the conductive terminals 63 and the package structure PKG are respectively located on two opposite sides of the package component 20, where some of the conductive terminals 63 are electrically connected to the package structure PKG through the redistribution lines 30 and the solder regions 42. In some embodiments, the conductive terminals 63 can be formed on the surface S2 of the package component 20 by a ball placement process and a reflow process. In some embodiments, the reflow process may be performed to reshape the conductive terminals 63 and thus there are good physical and metallurgical connections of the conductive terminals 63 to the package component 20.

Reference is made to FIGS. 7E and 7F. FIGS. 7E and 7F illustrate schematic views of packages 110 and 210, respectively, in accordance with some embodiments of the present disclosure. While FIGS. 7E and 7F illustrate embodiments of the packages 110 and 210 with different lid structure configurations than the package 10 in FIGS. 1-7D, 8, and 9, the present disclosure may repeat reference numerals and/or letters in the various examples. This repetition is for the purpose of simplicity and clarity and does not in itself dictate a relationship between the various embodiments and/or configurations discussed.

As shown in FIG. 7E, the lid structure 170 in the packages 110 can incorporate a recessed portion 170r to enhance thermal interface efficiency. The recessed portion 170r can includes three distinct areas: a central area C11, a transition area C12, and a peripheral area C13. The central area C11, a transition area C12, and a peripheral area C13 can have constant thicknesses T2, T3, and T4, respectively, contributing to a stepped structure S4, on the bottom surface of the recessed portion 170r. The stepped structure S4 can provide a more uniform and controlled application of the TIM 65 across the packages 110. In some embodiments, the stepped structure S4 can facilitate a gradual and more precise distribution of pressure and material during the assembly process, ensuring that the TIM layer maintains optimal contact between the package 110 and the lid structure 170.

As shown in FIG. 7F, the lid structure 270 of the packages 210 can have a protruding portion 270p protruding out from a back-side surface of the cover portion 70c. In other words, the protruding portion 270p with the cover portion 70c can form a stepped structure 270s on the back-side of the lid structure 270, positioned over the CoW area. A recessed portion 270r as shown in FIGS. 7A-7D can be formed on the protruding portion 270p. In some embodiments, a footprint of the protruding portion 270p can overlap with a footprint of the package structure PKG. In some embodiments, the shape of the protruding portion 270p can depend on the shape of the package structure PKG. For example, when the package structure PKG has a rectangular top view, the protruding portion 270p can exhibit a rectangular top view corresponding to the package structure PKG. In some embodiments, the cover portion 70c and the protruding portion 270p can be integrally formed. For example, the material of the protruding portion 270p can be the same as the material of the cover portion 70c. However, the disclosure is not limited thereto. In some alternative embodiments, the protruding portion 270p may be installed on the cover portion 70c. For example, the material of the protruding portion 270p may be different from the material of the cover portion 70c. In some embodiments, the protruding portion 270p can allows for a stronger and more secure attachment of the lid structure 70 to the package 210, providing better protection and stability.

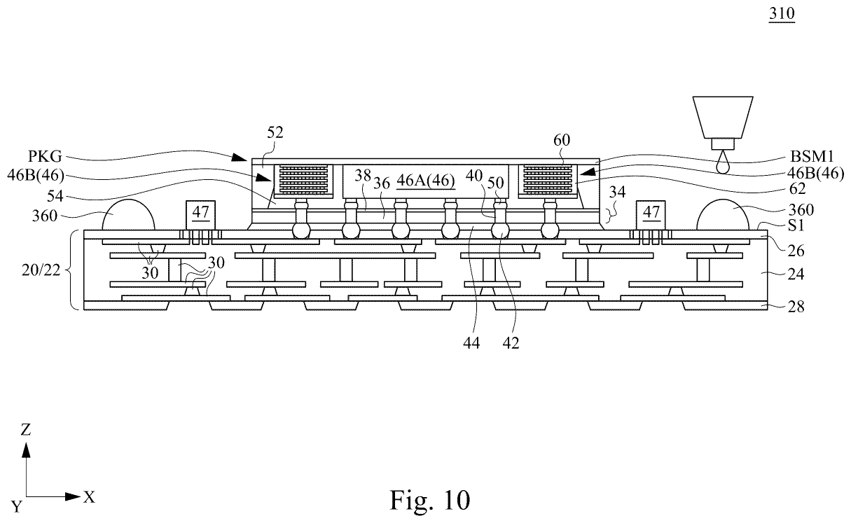

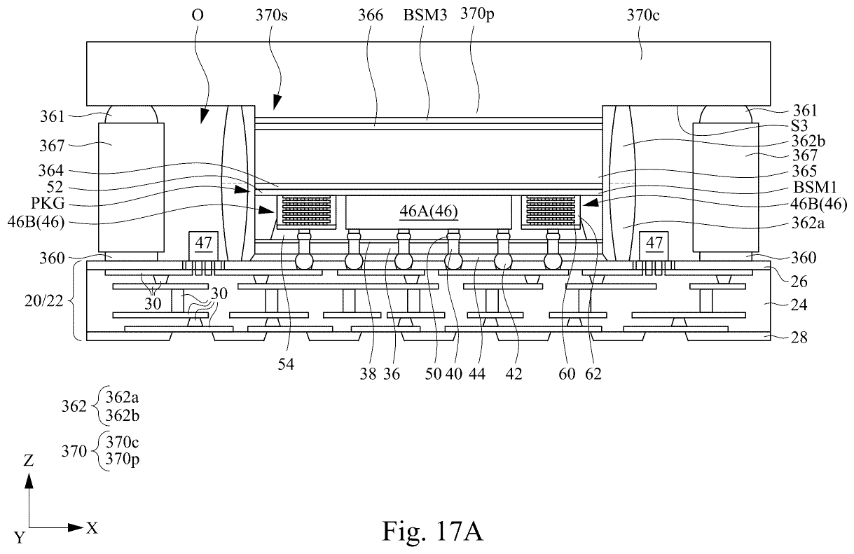

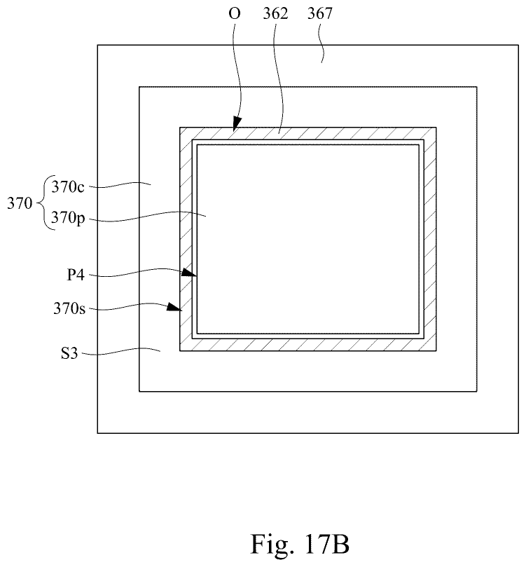

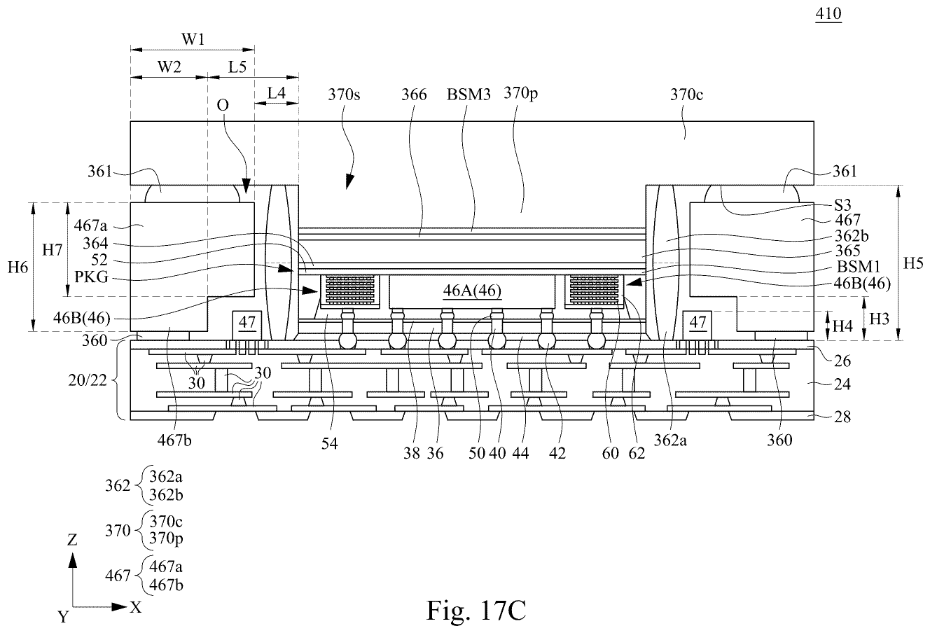

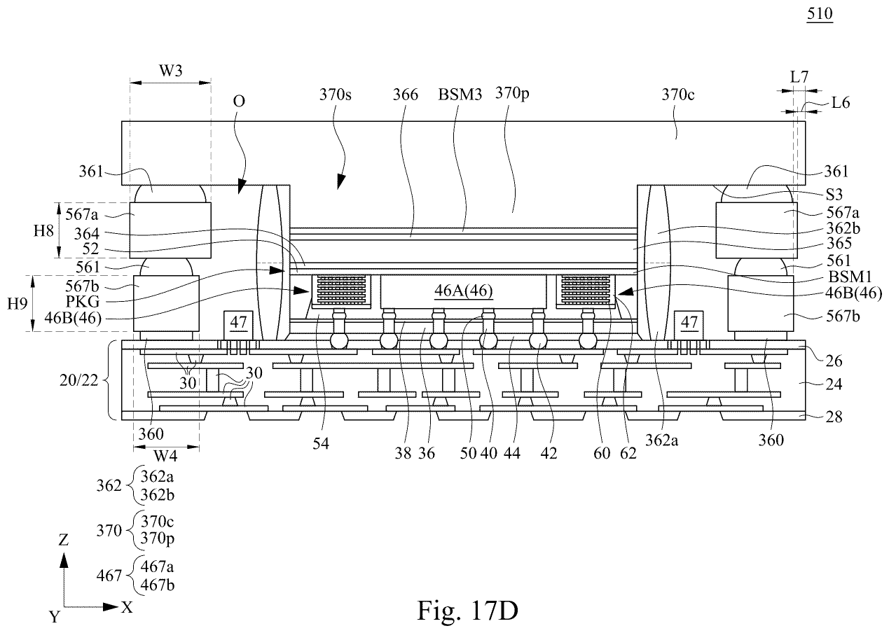

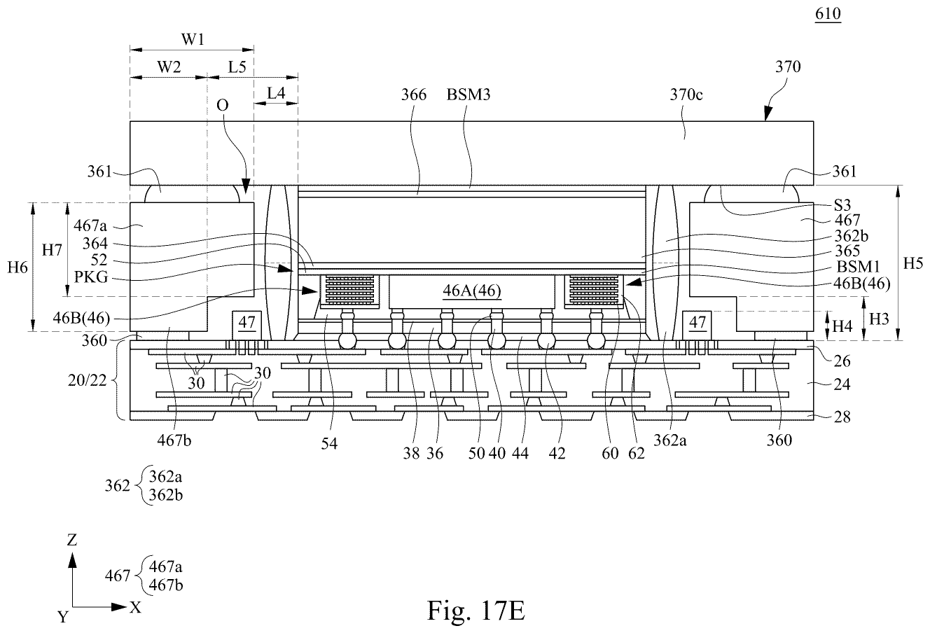

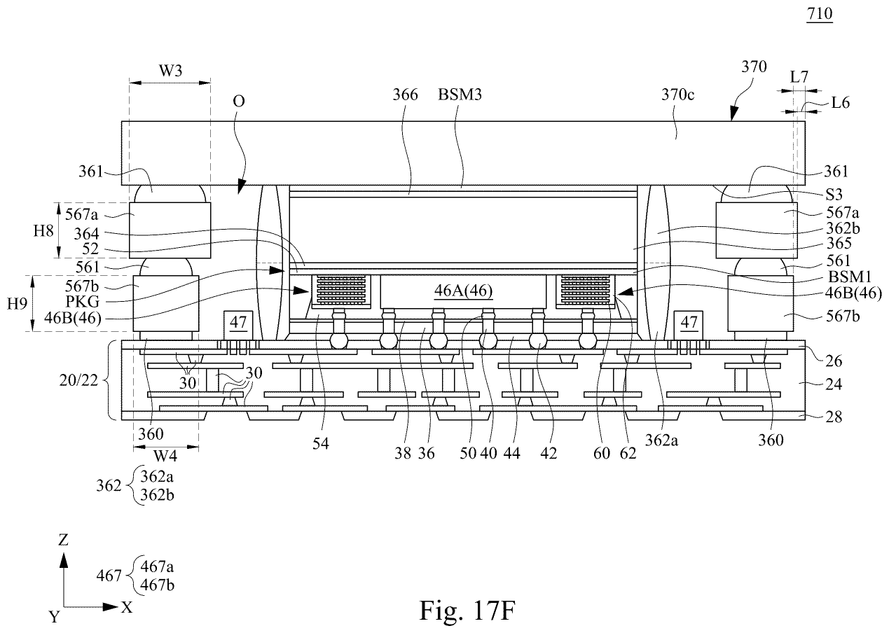

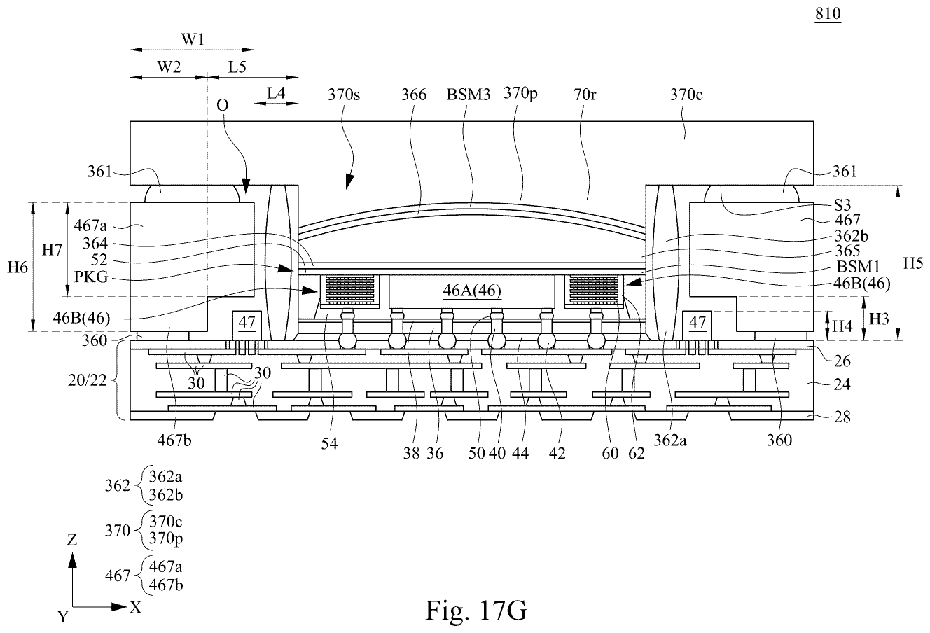

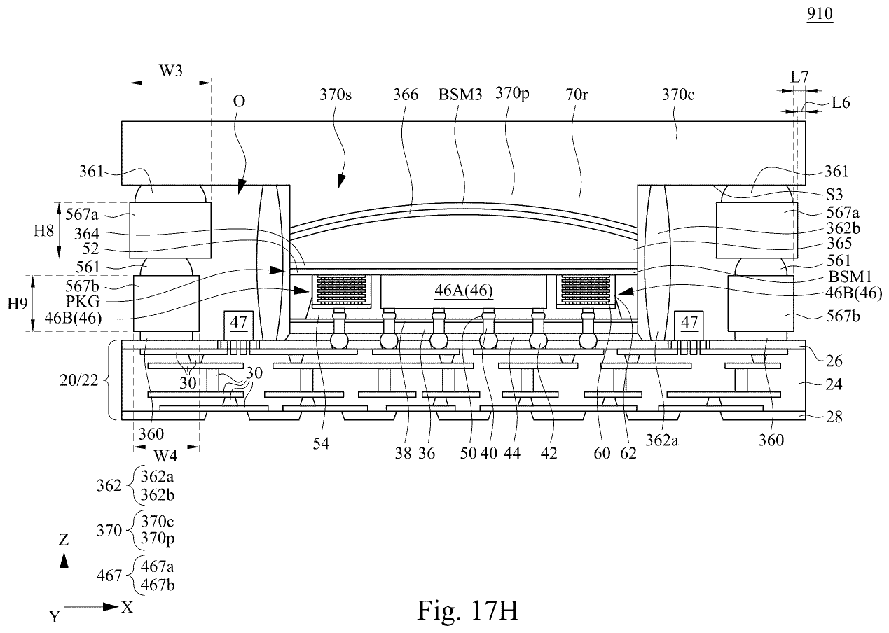

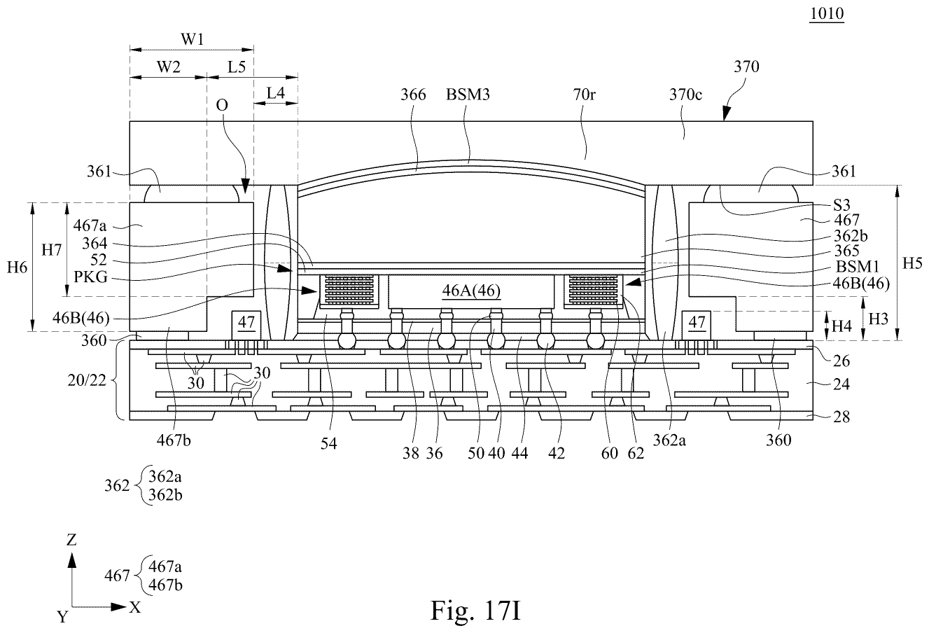

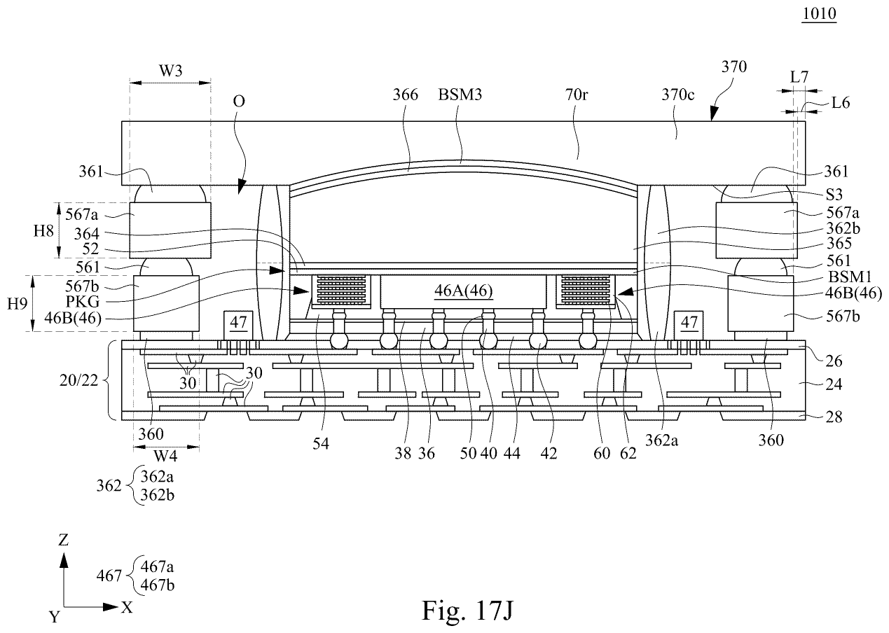

Reference is made to FIGS. 10-17B, 18, and 19. FIGS. 10-17B, 18, and 19 illustrate schematic views of intermediate stages in the formation of a package 310 in accordance with some embodiments of the present disclosure. The steps preceding FIG. 10 can correspond to those illustrated in FIGS. 1-2B. For an understanding of the processes and structures involved up to this step, please refer to FIGS. 1-2B. To avoid repetition, these preceding steps will not be reiterated in this section. Additionally, the present disclosure may repeat reference numerals and/or letters in the various examples. This repetition is for the purpose of simplicity and clarity and does not in itself dictate a relationship between the various embodiments and/or configurations discussed. FIGS. 10-17A, 18, and 19 illustrate cross-sectional views along a similar cross-section as reference cross-section A-A′ in FIG. 2B. FIG. 17B illustrates a top view of a lid structure 370 in accordance with some embodiments of the present disclosure. It is understood that additional operations can be provided before, during, and after the processes shown by FIGS. 10-17B, 18, and 19, and some of the operations described below can be replaced or eliminated, for additional embodiments of the method. The order of the operations/processes may be interchangeable.

Reference is made to FIG. 10. An adhesive layer 360 can be formed on the surface S1 of the package component 20. For example, the adhesive layer 360 can be formed near edges of the surface S1 of the package component 20 to surround/encircle the package structure PKG, the underfill 44, and the surface mount devices 47. In some embodiments, the adhesive layer 360 partially covers the surface S1 of the package component 20. The package structure PKG, the underfill 44, and the surface mount devices 47 are physically isolated from the adhesive layer 360. In some embodiments, the adhesive layer 360 has a ring-like shape in the plane view. In some embodiments, the pattern of the adhesive layer 360 may be designed based on the various design. For example, the adhesive layer 360 may have a linear shape, L shape, U shape, dot shape, etc. In some embodiments, the shape of the adhesive layer 360 can depend on the shape of the package component 20. For example, when the package component 20 is in wafer form (i.e., having a circular top view), the adhesive layer 360 can exhibit a circular ring-like shape from the top view. For example, when the package component 20 is in panel form (i.e., having a rectangular or squared top view), the adhesive layer 360 can exhibit a rectangular or squared ring-like shape from the top view. In some embodiments, the adhesive layer 360 can be applied onto the package component 20 through a dispensing process, a spin-coating process, or the like. In some embodiments, the adhesive layer 360 can have a thermal conductivity greater than about 0 W/m·K to 5 W/m·K. In some embodiments, the adhesive layer 360 can include a silicon-based material, an acrylic-base material, an epoxy-based polymer, or combinations thereof. However, the disclosure is not limited to. In some alternative embodiments, other polymeric materials having adhering property may be utilized as the adhesive layer 360.

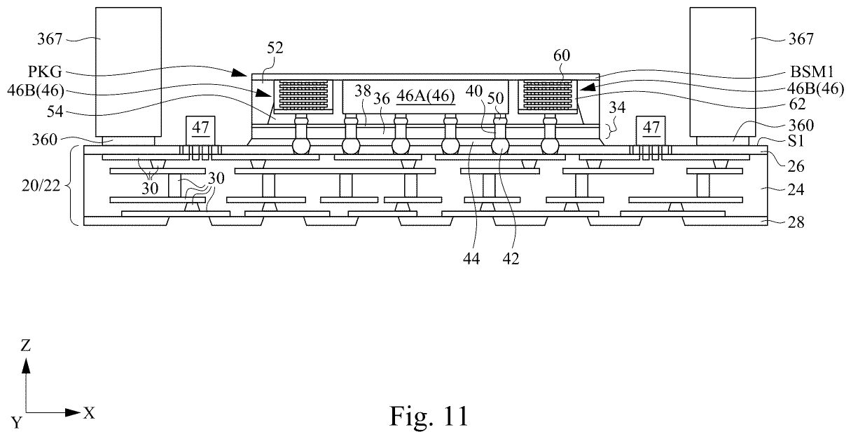

Reference is made to FIG. 11. A ring structure 367 is attached to the package component 20. In some embodiments, the ring structure 367 can be fabricated from robust materials such as stainless steel, Copper (Cu), Alloy42, among others, providing structural integrity and facilitating thermal management within the CoWoS configuration. In some embodiments, the ring structure 367 can be made of metal. In some embodiments, the Young's modulus of the ring structure 367 can range from about 50 GPa to about 200 GPa. In some embodiments, the ring structure 367 can encircle the package structure PKG and the surface mount devices 47. As shown in FIG. 11, the ring structure 367 can be spatially separated from the package structure PKG, the underfill 44, and the surface mount devices 47. In some embodiments, the top surface of the ring structure 367 can be located at a level height higher than the top surface of the conductive layer BSM1. Specifically, the ring structure 367 can be attached to the package component 20 through the adhesive layer 360. For example, the ring structure 367 can be first placed over the package component 20 to be in physical contact with the adhesive layer 360.

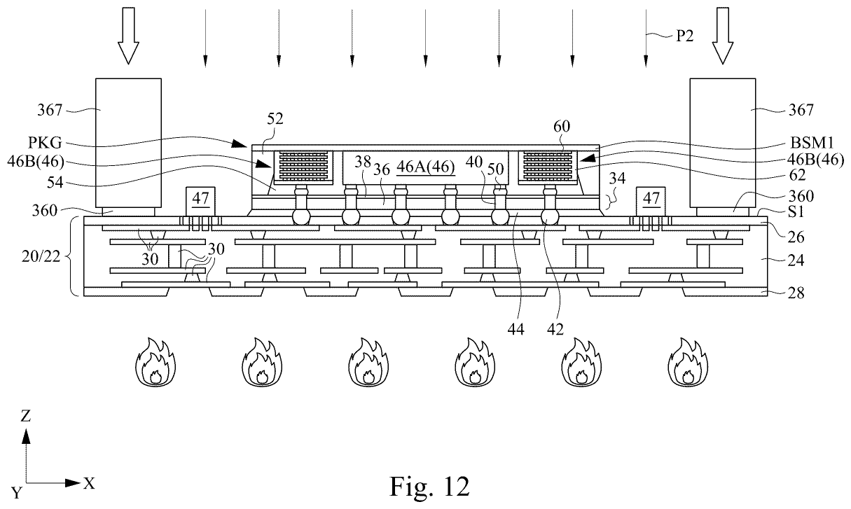

Reference is made to FIG. 12. The ring structure 367 can be pressed against the adhesive layer 360. In some embodiments, pressing the ring structure 367 against the adhesive layer 360 can include performing a heat clamping process P2, wherein the process temperature of the heat clamping process ranges from about 60° C. to about 300° C. In some embodiments, the clamping process P2 can be interchangeable referred to as a heat clamp process. Subsequently, a curing process can be performed on the adhesive layer 360, such that the ring structure 367 can be attached to the package component 20 through the adhesive layer 360. In detail, the curing process can be performed on the adhesive layer 360 to securely fix the ring structure 367 onto the package component 20. In some embodiments, the process temperature of the curing process ranges from about 60° C. to about 300° C. However, the disclosure is not limited to.

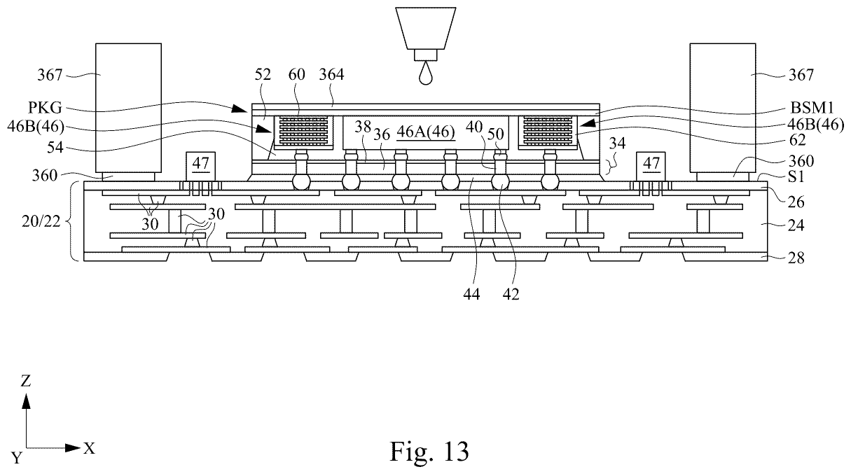

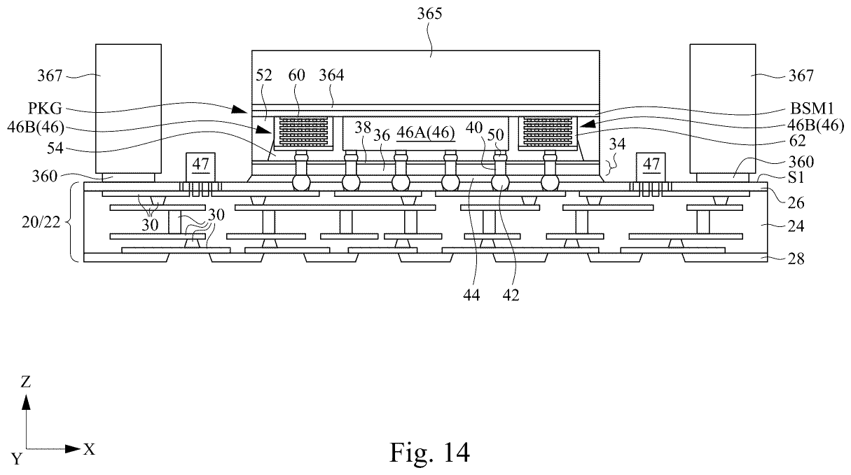

Reference is made to FIG. 13. A flux 364 may be applied onto the conductive layer BSM1 for better adhesion. For example, before the metallic TIM layer 365 (see FIG. 14) is placed on the conductive layer BSM1, the flux 364 can be formed over the package structure PKG. In some embodiments, the formation of the flux 364 can include performing a jetting process or a dispensing process. In some embodiments, the flux can be a solder flux. In some embodiments, the material of the flux 364 can include rosin or acids.

Reference is made to FIG. 14. The TIM layer 365 can be formed on the flux 364. In some embodiments, the TIM layer 365 can be in sheet type. In some embodiments, the TIM layer 365 can be formed on the flux 364 through a pick-and-place process. In some embodiments, the material of the TIM layer 365 can be soldered type material. In some embodiments, the TIM layer 365 can be formed by purely metallic materials and can be interchangeable referred to as a metal thermal interface material. In some embodiments, the TIM layer 365 can be free of organic material and polymeric material. In some embodiments, the material of the TIM layer 365 includes a metallic material, such as indium, copper, tin, Ag, or an alloy thereof. In some embodiments, the thermal conductivity of the TIM layer 365 ranges from about 10 W/(m·K) to about 90 W/(m·K). In some embodiments, the Young's modulus of the TIM layer 365 ranges from about 5 GPa to about 70 GPa.

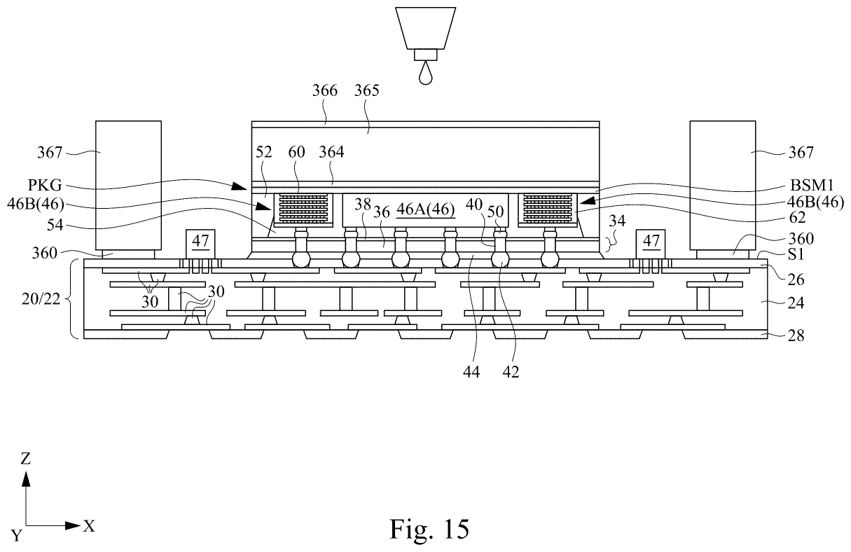

Reference is made to FIG. 15. A flux 366 may be applied onto the TIM layer 365 for better adhesion. For example, before a lid structure 370 (see FIG. 7A) is placed on the TIM layer 365, the flux 366 can be formed over the TIM layer 365. In some embodiments, the formation of the flux 66 can include performing a jetting process or a dispensing process. In some embodiments, the flux can be a solder flux. In some embodiments, the material of the flux 366 can include rosin or acids.

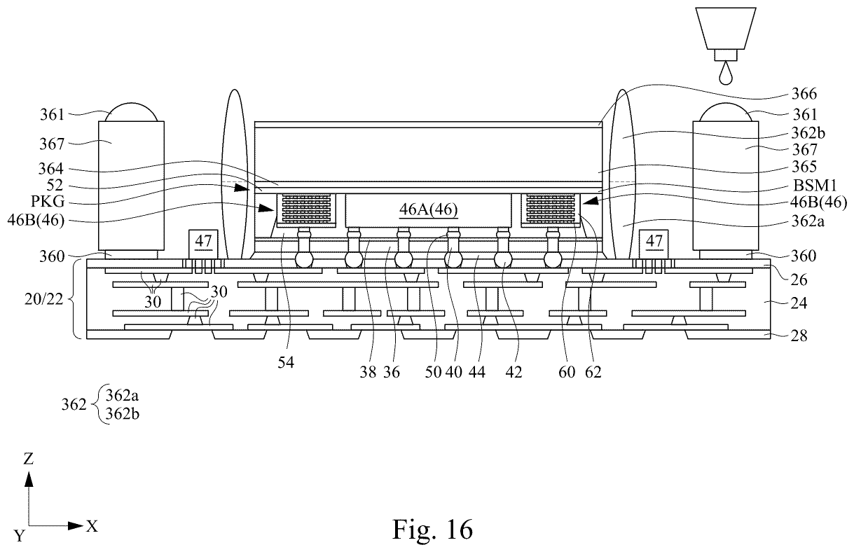

Reference is made to FIG. 16. An adhesive structure 361 can be formed over the ring structure 367, and an adhesive structure 362 can be formed over the package component 20. Specifically, the adhesive structure 361 can have a ring-like shape in the plane view. In some embodiments, the pattern of the adhesive structure 361 may be designed based on the various design. For example, the adhesive structure 361 may have a linear shape, L shape, U shape, dot shape, etc. In some embodiments, the shape of the adhesive structure 361 can depend on the shape of the ring structure 367. In some embodiments, the adhesive structure 361 can be interchangeable referred to as an adhesive layer.

The adhesive structure 362 can be formed near the package structure PKG to surround/encircle the package structure PKG. The adhesive structure 362 can be situated between the package structure PKG and the surface mount devices 47. On the other hand, the adhesive structure 361 can surround/encircle the adhesive structure 362. In some embodiments, the adhesive structure 362 can have a ring-like shape in the plane view. In some embodiments, the adhesive structure 362 can be a layered structure having a number of layers vertical stacked with each other, and the number of layers is greater than 2, such as 2, 3, 4, or 5. By way of example and not limitation, the adhesive structure 362 can be a two-layer ring structure having a first layer 362a and a second layer 362b over and in contact with a top portion of the first layer 362a. In some embodiments, the first layer 362a of the adhesive structure 362 can be interchangeable referred to as a first adhesive layer, and the second layer 362b of the adhesive structure 362 can be interchangeable referred to as a second adhesive layer. In some embodiments, the pattern of the adhesive structure 362 may be designed based on the various design. For example, the adhesive structure 362 may have a linear shape, L shape, U shape, dot shape, etc. In some embodiments, the shape of the adhesive structure 362 can depend on the shape of the package component 20. For example, when the package component 20 can be in panel form (i.e., having a rectangular or squared top view), the adhesive structure 362 can exhibit a rectangular or squared ring-like shape from the top view.

In some embodiments, the adhesive structures 361 and 362 can be applied onto the ring structure 367 and the package component 20 through a dispensing process, a spin-coating process, or the like. The adhesive structures 361 and the first layer 362a of adhesive structure 362 may be formed first, and then the second layer 362b of the adhesive structure 362 may be formed on the first layer 362a of the adhesive structure 362. The formation of adhesive structures 361 and 362 within semiconductor packaging can be flexible, accommodating different assembly processes. In some embodiments, the adhesive structure 362 can be formed after the adhesive structure 361. In this sequence, the broader boundary adhesive structure 361 can be applied first, circling the perimeter of the package component. This initial application can provide a foundational layer that secures the outer edges of the assembly. Following this, the more centrally located adhesive structure 362 can be applied, surrounding the TIM layer 365 and other internal components. In some embodiments, the adhesive structure 362 can be formed before adhesive structure 361. In some embodiments, the adhesive structure 362 can have a width narrower than a width of the adhesive structure 361.

In some embodiments, the adhesive structure 361/362 can have a thermal conductivity greater than about 0 W/m·K to 5 W/m·K. In some embodiments, the adhesive structure 361/362 can include a silicon-based material, an acrylic-base material, an epoxy-based polymer, or combinations thereof. However, the disclosure is not limited to. In some alternative embodiments, other polymeric materials having adhering property may be utilized as the adhesive structure 361/362. In some embodiments, the adhesive structure 362 can be made of a same material as the adhesive structure 361. In some embodiments, the adhesive structure 362 can be made of a different material than the adhesive structure 361. In some embodiments, the first layer 362a of the adhesive structure 362 can be made of a different material than the second layer 362b of the adhesive structure 361, and thus the first and second layers 362a and 362b may form a distinguishable interface therebetween. In some embodiments, the first layer 362a of the adhesive structure 362 can be made of a same material as the second layer 362b of the adhesive structure 361, and thus the first and second layers 362a and 362b may not form a distinguishable interface therebetween.

Reference is made to FIGS. 17A and 17B. A lid structure 370 can be placed over the ring structure 367, the package component 20, the package structure PKG, and the surface mount devices 47, such that the package structure PKG and the TIM layer 365 can be located between the package component 20 and the lid structure 370. The lid structure 370 can serve the function of heat dissipation. In other words, the heat generated during operation of the package structure PKG may be dissipated through the path created by the lid structure 370. The lid structure 370, the ring structure 367, and the package component 20 together enclose the package structure PKG and the surface mount devices 47. In other words, the lid structure 370 and the ring structure 367 can be formed to accommodate the package structure PKG and/or the surface mount devices 47. For example, a cover portion 370b of the lid structure 70 and the ring structure 367 may exhibit an upside down U-shape in a cross-sectional view, as shown in FIG. 17A. In some embodiments, the lid structure 370 can be made of metal, plastic, ceramics, or the like. The metal for the lid structure 370 may include, but not limit to, copper, stainless steel, solder, gold, nickel, molybdenum, NiFe or NiFeCr. In some embodiments, the thermal conductivity of the lid structure 70 ranges from about 80 W/(m·K) to about 450 W/(m·K). In some embodiments, the Young's modulus of the lid structure 70 ranges from about 50 GPa to about 200 GPa.

In some embodiments, the combination of the ring structure 367 and the flat lid structure 370 in packaging 310 can mitigate warpage during the ball mount reflow process. By implementing a flat lid structure 370 atop the ring structure 367, this structure can introduce structural stability and support across the package 310 during the reflow process. This stability can ensure that the TIM layer 365 can remain uniformly spread across the contact surfaces between the package structure PKG and the lid structure 370, ensuring that there are no air gaps or uneven areas that could act as thermal insulators. As a result, the TIM layer coverage can remain greater than about 95% post-reflow for achieving optimal thermal performance and reliability of the semiconductor device.

In some embodiments, the lid structure 370 can include a cover portion 370c and a protruding portion 370p. The cover portion 370c can extend along the direction X and the direction Y and can be in sheet type. In some embodiments, the cover portion 370c can be interchangeable referred to as a bulk portion. The protruding portion 370p can protrude out from a surface S3 (or back-side surface) of the cover portion 370c. In some embodiments, the protruding portion 370p can be thicker than the adhesive structure 361. In other words, the protruding portion 370p with the cover portion 370c can form a stepped structure 370s on the back-side of the lid structure 370, positioned over the CoW area. This stepped structure 370s can be tailored to match the height of the ring structure 367, ensuring a fit and an optimized thermal interface. However, not all embodiments feature this stepped structure, allowing for flexibility in application. In some embodiments, the cover portion 370c and the protruding portion 370p can be integrally formed. For example, the material of the protruding portion 370p can be the same as the material of the cover portion 370c. However, the disclosure is not limited thereto. In some alternative embodiments, the protruding portion 370p may be installed on the cover portion 370c. For example, the material of the protruding portion 370p may be different from the material of the cover portion 370c. In some embodiments, the lid structure 370 can have a maximum dimension T5 (or thickness) in a range from about 0.5 to 4.0 mm, such as about 0.5, 1.0, 1.5, 2.0, 2.5, 3.0, 3.5, or 4.0 mm.

The lid structure 370 can be securely fixed onto the ring structure 367 through attaching the cover portion 370c to the adhesive structure 361, such that the protruding portion 370p can extend into the opening O of the ring structure 367. In some embodiments, the contour P4 (see FIG. 17B) of the protruding portion 370p can be substantially corresponding to the contour of the opening O of the ring structure 367. Therefore, the TIM layer 365 can be sandwiched between the protruding portion 370p of the lid structure 370 and the package structure PKG.

In some embodiments, prior to the attachment of the lid structure 370, a conductive layer BSM3 can be formed on the protruding portion 370p of the lid structure 370. In detail, as illustrated in FIG. 17A, the conductive layer BSM3 and the protruding portion 370p are disposed in the opening O of the ring structure 367. It is noted that the conductive layer BSM3 can be utilized to promote adhesion between the TIM layer 365 and the lid structure 370, and can be referred to as a backside metallization or a backside metal layer. In some embodiments, the material of the conductive layer BSM3 can be the same as the material of the conductive layer BSM1. In alternative some embodiments, the material of the conductive layer BSM3 can be different from the material of the conductive layer BSM1. In some embodiments, the conductive layer BSM3 can be formed on the lid structure 370 through a plating, sputtering or dispensing process. In some embodiments, the material of the conductive layer BSM3 can include metal, such as Al, Ti, Ni, V, Au, Ag or Cu. In some embodiments, the conductive layer BSM3 can be integrated as an Au plated heat sink. That is, the back-side of the lid structure 370 can be coated with gold (Au) to improve thermal conductivity and resist oxidation, while its bulk composition may include materials like copper (Cu) or aluminum (Al). However, the disclosure is not limited thereto. In some alternative embodiments, there is no conductive layer BSM3 formed on the lid structure 370.

Specifically, after the conductive layer BSM3 is be formed on the lid structure 370, the lid structure 370 and the conductive layer BSM3 can be placed above the TIM layer 365 and the ring structure 367, such that the conductive layer BSM3 can be in physical contact with the top surface of the flux 366, and the peripheral portion of the cover portion 370c of the lid structure 370 can be in physical contact with the adhesive structure 361. Thereafter, the lid structure 370 and the conductive layer BSM3 are pressed against the TIM layer 365 and the adhesive structure 361.

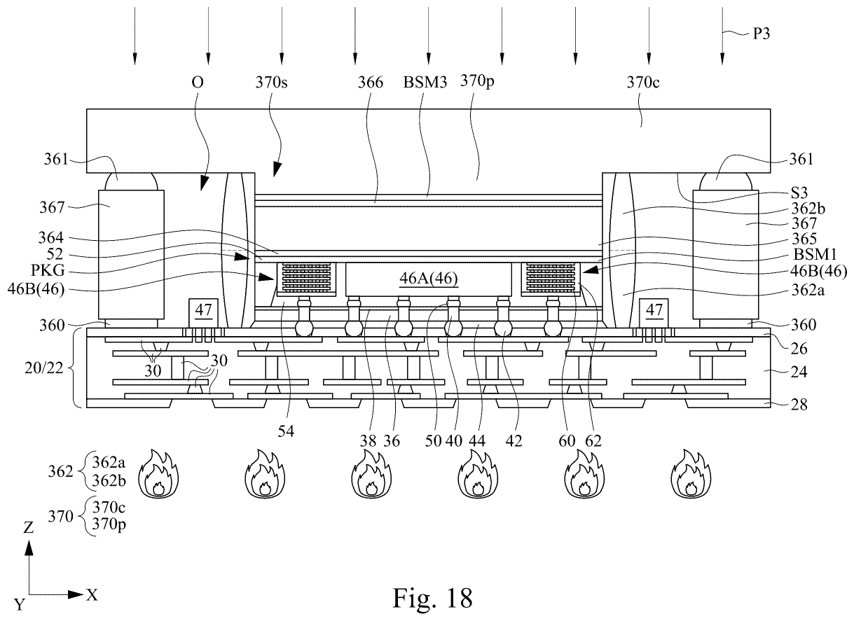

Reference is made to FIG. 18. The lid structure 370 and the conductive layer BSM3 are pressed against the TIM layer 365 and the adhesive structures 361 and 362. In some embodiments, pressing the lid structure 370 and the conductive layer BSM3 against the TIM layer 365 and the adhesive structures 361 and 362 can include performing a heat clamping process P3, wherein the process temperature of the heat clamping process ranges from about 60° C. to about 300° C. In some embodiments, the clamping process P3 can be interchangeable referred to as a heat clamp process. Subsequently, a curing process can be performed on the adhesive structures 361 and 362, such that the lid structure 370 can be attached to the package component 20 through the adhesive structures 361 and 362. In detail, the curing process can be performed on the adhesive structures 361 and 362 to securely fix the lid structure 370 onto the package component 20. In some embodiments, the process temperature of the curing process ranges from about 60° C. to about 300° C. However, the disclosure is not limited to. In some embodiments, during the curing process, the lid structure 370 can be attached to the package structure PKG through the TIM layer 365. That is to say, in such embodiments, during the curing process, there is a good physical and metallurgical connection of the lid structure 370 to the package structure PKG.

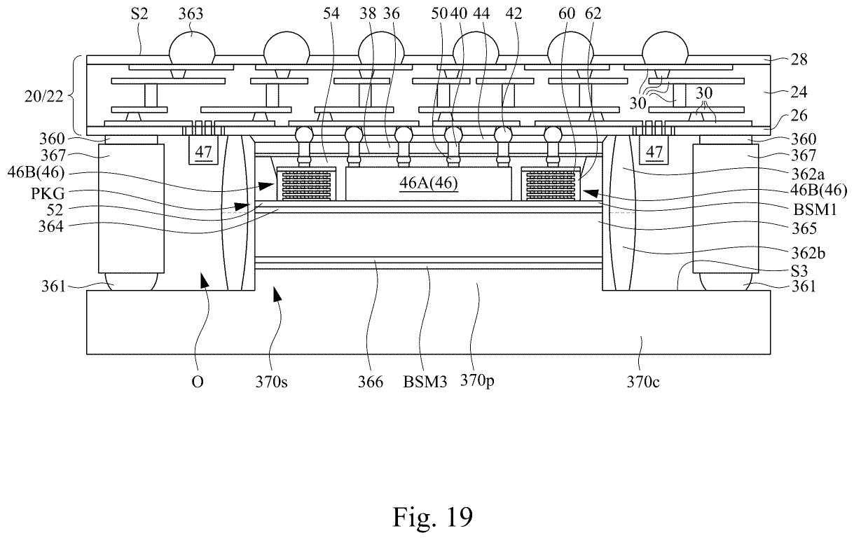

Reference is made to FIG. 19. A plurality of conductive terminals 363 can be formed on the surface S2 of the package component 20. In some embodiments, the conductive terminals 363 are solder balls, ball grid array (BGA) balls, or the like. In some embodiments, the conductive terminals 363 are made of a conductive material with low resistivity, such as Sn, Pb, Ag, Cu, Ni, Bi, or an alloy thereof. In some embodiments, the conductive terminals 363 can be in physical contact with the redistribution lines 30 (or routing patterns) exposed at the surface S2 of the package component 20. In some embodiments, the conductive terminals 363 can be used to physically and electrically connect the package component 20 to other devices, packages, connecting components, and the like. That is to say, the conductive terminals 363 can be used for providing physical and/or electrical connection to external components. As shown in FIG. 19, the conductive terminals 363 and the package structure PKG are respectively located on two opposite sides of the package component 20, where some of the conductive terminals 363 are electrically connected to the package structure PKG through the redistribution lines 30 and the solder regions 42. In some embodiments, the conductive terminals 363 can be formed on the surface S2 of the package component 20 by a ball placement process and a reflow process. In some embodiments, the reflow process may be performed to reshape the conductive terminals 363 and thus there are good physical and metallurgical connections of the conductive terminals 363 to the package component 20.

Reference is made to FIGS. 17C-17J. FIGS. 17C-17J illustrate schematic views of packages 410, 510, 610, 710, 810, 910, 1010, and 1110 in accordance with some embodiments of the present disclosure. While FIGS. 17C-17J illustrate embodiments of the package 410, 510, 610, 710, 810, 910, 1010, and 1110 with different lid structure configurations and/or different ring structure configurations than the package 310 in FIGS. 10-17B, 18, and 19, the present disclosure may repeat reference numerals and/or letters in the various examples. This repetition is for the purpose of simplicity and clarity and does not in itself dictate a relationship between the various embodiments and/or configurations discussed.

As shown in FIG. 17C, the ring structure 467 in package 410 can have an inverted L-shaped profile when viewed in cross-section, resulting in the upper portion 467a having a ring thickness than the lower portion 467b, with ring thicknesses W1 and W2 respectively. The upper portion 467a of the ring structure 467 is positioned closer to the package structure PKG, at a lateral distance L4, while the lower part 467b of the ring structure 467 is set further away, at a lateral distance L5, making the distance L5 larger than the distance L4, allowing the upper portion of the 467a of the ring structure 467 to extend laterally towards the package structure PKG, offering additional coverage over at least a portion of the surface mount device 47. Therefore, the ring structure 467 can protect the surface mount devices during assembly and operation. Additionally, by extending laterally towards the package structure PKG, the ring structure 467 can help in distributing stress more evenly across the package 410, reducing the likelihood of mechanical failure and enhancing the warpage control ability. In some embodiments, the protrusion of the upper portion 467a of the ring structure 467 close to die edge can be interchangeable referred to as a bridge structure.

The upper portion 467a of the ring structure 467 can have a distance H3 from the package component 20, ensuring it does not interfere with the surface mount device 47, which have a height H4 from the package component 20. That is, the distance H3 is greater than the height H4, which in turn avoids physical contact between the ring structure 467 and the surface mount device 47, maintaining the integrity of the assembly. In some embodiments, the upper portion 467a of the ring structure 467 is vertical spaced apart from the surface mount device 47 by a distance in a range from about 0.05 to 0.30 mm, such as about 0.05, 0.10, 0.15, 0.20, 0.25, or 0.30 mm. Moreover, the exterior wall of the upper portion 467a of the ring structure 467 can align with the exterior wall of the lower portion 467b of ring structure 467, ensuring a unified appearance. The cover portion 370c can have a distance H5 from the package component 20, and the distance is greater than a combination of the distance H3 and the height H4. The ring structure 467 can have a vertical dimension H6 (or ring width) greater than the distance H5, and the upper portion 467a of the ring structure 467 can have a vertical dimension H7 (or ring width). In some embodiments, the vertical dimension H7 of the upper portion 467a of the ring structure 467 can be greater than the thickness of the TIM layer 365.

As shown in FIG. 17D, two stacked ring structures 567a and 567b are positioned between the package component 20 and the cover portion 370c to enhance the mechanical stability of the package 510. Additionally, by positioning an adhesive structure 561 between these two ring structures 567a and 567b, it not only facilitates a stronger bond within the assembly but also provides additional layers for mechanical stress distribution. This configuration is a modification from the single ring structure 367, as previously illustrated in the FIGS. 10-17B, 18, and 19. Expanding beyond the dual-ring configuration, the possibility of incorporating more than two ring structures, such as 3, 4, or up to 10, suggests a solution to match different thermal and mechanical requirements of various packages. More rings mean more interfaces for stress distribution, allowing for performance needs.

In some embodiments, the upper ring structure 567a can have a ring thickness greater than the lower ring structures 567b, with ring thicknesses W3 and W4 respectively. The upper ring structure 567a is positioned closer to the package structure PKG, at a lateral distance L6, while the lower ring structures 567b is set further away, at a lateral distance L7, making the distance L7 larger than the distance L6, allowing the upper ring structure 567a to extend laterally towards the package structure PKG, offering additional coverage over at least a portion of the surface mount device 47. Therefore, the upper ring structure 567a can protect the surface mount devices during assembly and operation.

In some embodiments, the upper ring structures 567a can have a vertical dimension H8 (or ring width), the lower ring structures 567b can have a vertical dimension H9 (or ring width), and the vertical dimension H8 is greater than the vertical dimension H9. In some embodiments, the distance H5 between the cover portion 370c and the package component 20 is greater than a combination of the vertical dimension H8 and the vertical dimension H9. In some embodiments, the upper ring structures 567a can have a lateral distance L8 to an edge of the cover portion 370c, the lower ring structures 567b can have a lateral distance L9 to the edge of the cover portion 370c, and the lateral distance L8 is less than the lateral distance L9. By way of example and not limitation, the lateral distance L8 can be less than about 0.8 mm, such as about 0.1, 0.2, 0.3, 0.4, 0.5, 0.6, 0.7, or 0.8 mm. The lateral distance L9 can be less than about 0.8 mm, such as about 0.1, 0.2, 0.3, 0.4, 0.5, 0.6, 0.7, or 0.8 mm.

Reference is made to FIGS. 17E and 17F. The packages 610 and 710 illustrated in FIGS. 17E and 17F can be seen as variants of the packages 410 and 510 illustrated in FIGS. 17C and 17D, respectively. The difference between these sets of packages may lies in their lid structures. Specifically, the lid structures 670 and 770 in FIGS. 17E and 17F lack the protruding portion 370p present in the lid structures 470 and 570. This difference may signify that while the lid structures 470 and 570 incorporate a protruding portion 370p that likely serves to enhance mechanical support and thermal interface efficiency, the lid structures 670 and 770 can offer a simplified configuration that does away with this feature. The absence of the protruding portion 370p could imply variations in the approach to thermal management and mechanical stability, potentially simplifying the manufacturing process or addressing different packaging requirements.

Reference is made to FIGS. 17G and 17H. The packages 810 and 910 illustrated in FIGS. 17G and 17H can be seen as variants of the packages 410 and 510 illustrated in FIGS. 17C and 17D, respectively. The difference between these sets of packages may lies in their lid structures. Specifically, the protruding portions 370p of the lid structures 870 and 970 can incorporate recessed portions 70r outlined in the earlier FIGS. 1-7D, 8, and 9. By combining protruding portion 370p with recessed portions 70r, the packages 810 and 910 can enhance the efficiency of thermal management and mechanical stability. The recessed portions 70r within the protruding portion 370p can help in distributing thermal interface materials more evenly, minimizing thermal resistance and optimizing heat dissipation.

Reference is made to FIGS. 171 and 17J. The packages 1010 and 1110 illustrated in FIGS. 171 and 17J can be seen as variants of the packages 610 and 710 illustrated in FIGS. 17E and 17F, respectively. The difference between these sets of packages may lies in their lid structures. Specifically, the cover portions 370c of the lid structures 1070 and 1170 can incorporate recessed portions 70r outlined in the earlier FIGS. 1-7D, 8, and 9. By combining the cover portion 370c with recessed portions 70r, the packages 1010 and 1110 can enhance the efficiency of thermal management and mechanical stability. The recessed portions 70r within the cover portion 370c can help in distributing thermal interface materials more evenly, minimizing thermal resistance and optimizing heat dissipation.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides a lid structure to achieve stable control over void rates when the thickness of the TIM layer is reduced (e.g., by about 80% to less than 60 micrometers of the TIM layer), enabling the reduction in thermal resistance (e.g., 30 to 50% reduction to less than 3 K·mm²/W) in the TIM layer. By employing a lid structure with a recessed portion (e.g., a hump) over the TIM layer, the thickness variation across the package structure can be reduced (e.g., less than 20 micrometers), which in turn enhances power efficiency (e.g., by 2 to 5%) and expands the reliability window. Additionally, the lid structure can be modified to combine a ring structure with a flat lid, which in turn mitigates warpage variations during the ball mount reflow process, ensuring that the TIM layer maintains over, such as 95% coverage, after reflow. Furthermore, a ring structure can be equipped with a bridge structure near the die edge can improve warpage control, further stabilizing the assembly process and enhancing the overall performance and reliability of the package.

In some embodiments, a method includes bonding a package component to a substrate; forming a thermal interface material (TIM) over the package component; forming a first adhesive layer over the substrate, the first adhesive layer laterally surrounding the package component; attaching a lid to the TIM and the first adhesive layer, wherein the lid has a recessed portion overlapping the TIM. In some embodiments, the recessed portion of the lid has a concave bottom surface, and after attaching the lid to the TIM, a top surface of the TIM is conform to the concave bottom surface of the lid. In some embodiments, from a top view, the recessed portion of the lid has a central region and a first ring-shaped region surrounding the central region, and a vertical thickness of the central region of the lid is thinner than a vertical thickness of the first ring-shaped region of the lid. In some embodiments, from the top view, the recessed portion of the lid has a second ring-shaped region surrounding the first ring-shaped region, and the vertical thickness of the first ring-shaped region of the lid is thinner than a vertical thickness of the second ring-shaped region of the lid. In some embodiments, the first adhesive layer has a top in a position higher than a top surface of the package component, and the recessed portion of the lid does not overlap the first adhesive layer. In some embodiments, the lid comprises copper, nickel, stainless steel, ferrum, argentum, aurum, or combinations thereof. In some embodiments, the TIM has a vertical thickness less than about 60 μm. In some embodiments, the first adhesive layer comprises a silicon-based material, an acrylic-base material, an epoxy-based polymer, or combinations thereof. In some embodiments, the package component forms a land grid array package. In some embodiments, the package component forms a ball grid array package. In some embodiments, the method further includes forming a second adhesive layer over the substrate prior to attaching the lid, the second adhesive layer laterally surrounding the package component, wherein the step of attaching the lid comprises attaching the lid to the second adhesive layer, and the second adhesive layer does not overlap the recessed portion of the lid. In some embodiments, the step of forming the first adhesive layer is performed prior to the step of forming the second adhesive layer. In some embodiments, the step of forming the first adhesive layer is performed after the step of forming the second adhesive layer.

In some embodiments, a method includes bonding a package structure to a substrate; attaching a ring structure on the substrate, the ring structure surrounding the package structure, wherein a ring thickness of an upper portion of the ring structure is greater than a ring thickness of a lower portion of the ring structure; forming a thermal interface material (TIM) layer over the package structure; attaching a lid structure to the TIM layer and the ring structure. In some embodiments, a lateral distance from the upper portion of the ring structure to the package structure is shorter than a lateral distance from the lower portion of the ring structure to the package structure. In some embodiments, an outer sidewall of the upper portion of the ring structure is aligned with an outer sidewall of the lower portion of the ring structure. In some embodiments, the method further includes bonding a surface mount device to the substrate prior to attaching the lid structure, wherein after attaching the lid structure, the upper portion of the ring structure at least partially overlaps the surface mount device, and the lower portion of the ring structure does not overlap the surface mount device. In some embodiments, after attaching the lid structure, the lid structure has a first portion over the TIM layer and a second portion over the ring structure, and a thickness of the first portion of the lid structure is thicker than a thickness of the second portion of the lid structure.

In some embodiments, a package includes a substrate, a package component, a thermal interface material (TIM) layer, a first ring structure, a second ring structure, and a lid structure. The package component is over a substrate. The TIM layer is over the package component. The first ring structure is over the substrate and surrounds the package component. The second ring structure is over the first ring structure. The lid structure is over the TIM layer and the second ring structure. In some embodiments, a lateral distance from the second ring structure to the package component is shorter than a lateral distance from the first ring structure to the package component. In some embodiments, a lateral distance from an outer sidewall of the second ring structure to an edge of the lid structure is shorter than a lateral distance from an outer sidewall of the first ring structure to the edge of the lid structure. In some embodiments, a ring width of the second ring structure is greater than a ring width of the first ring structure. In some embodiments, the package further includes a surface mount device over the substrate, wherein the second ring structure at least partially overlaps the surface mount device, and the first ring structure does not overlap the surface mount device.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
bonding a package component to a substrate;
forming a thermal interface material (TIM) over the package component;
forming a first adhesive layer over the substrate, the first adhesive layer laterally surrounding the package component; and
attaching a lid to the TIM and the first adhesive layer, wherein the lid has a recessed portion overlapping the TIM on the substrate.

2. The method of claim 1, wherein the recessed portion of the lid has a concave bottom surface, and after attaching the lid to the TIM, a top surface of the TIM is conformal to the concave bottom surface of the lid.

3. The method of claim 1, wherein from a top view, the recessed portion of the lid has a central region and a first ring-shaped region surrounding the central region, and a vertical thickness of the central region of the lid is thinner than a vertical thickness of the first ring-shaped region of the lid.

4. The method of claim 3, wherein from the top view, the recessed portion of the lid has a second ring-shaped region surrounding the first ring-shaped region, and the vertical thickness of the first ring-shaped region of the lid is thinner than a vertical thickness of the second ring-shaped region of the lid.

5. The method of claim 1, wherein the first adhesive layer has a top in a position higher than a top surface of the package component, and the recessed portion of the lid does not overlap the first adhesive layer.

6. The method of claim 1, further comprising:
forming a second adhesive layer over the substrate prior to attaching the lid, the second adhesive layer laterally surrounding the package component, wherein the step of attaching the lid comprises attaching the lid to the second adhesive layer, and the second adhesive layer does not overlap the recessed portion of the lid.

7. The method of claim 6, wherein the step of forming the first adhesive layer is performed prior to the step of forming the second adhesive layer.

8. The method of claim 6, wherein the step of forming the first adhesive layer is performed after the step of forming the second adhesive layer.

9. The method of claim 1, wherein the first adhesive layer comprises a silicon-based material, an acrylic-base material, an epoxy-based polymer, or combinations thereof.

10. The method of claim 1, wherein the TIM has a vertical thickness less than about 60 μm.

11. A method, comprising:
bonding a package structure to a substrate;
attaching a ring structure to the substrate, the ring structure surrounding the package structure, wherein a ring thickness of an upper portion of the ring structure is greater than a ring thickness of a lower portion of the ring structure;
forming a thermal interface material (TIM) layer over the package structure; and
attaching a lid structure to the TIM layer and the ring structure.

12. The method of claim 11, wherein a lateral distance from the upper portion of the ring structure to the package structure is shorter than a lateral distance from the lower portion of the ring structure to the package structure.

13. The method of claim 11, wherein an outer sidewall of the upper portion of the ring structure is aligned with an outer sidewall of the lower portion of the ring structure.

14. The method of claim 11, further comprising:
bonding a surface mount device to the substrate prior to attaching the lid structure, wherein after attaching the lid structure, the upper portion of the ring structure at least partially overlaps the surface mount device, and the lower portion of the ring structure does not overlap the surface mount device.

15. The method of claim 11, wherein after attaching the lid structure, the lid structure has a first portion over the TIM layer and a second portion over the ring structure, and a thickness of the first portion of the lid structure is thicker than a thickness of the second portion of the lid structure.

16. A package, comprising:
a package component over a substrate;
a thermal interface material (TIM) layer over the package component,
a first ring structure over the substrate and surrounding the package component;
a second ring structure over the first ring structure; and
a lid structure over the TIM layer and the second ring structure.

17. The package of claim 16, wherein a lateral distance from the second ring structure to the package component is shorter than a lateral distance from the first ring structure to the package component.

18. The package of claim 16, wherein a lateral distance from an outer sidewall of the second ring structure to an edge of the lid structure is shorter than a lateral distance from an outer sidewall of the first ring structure to the edge of the lid structure.

19. The package of claim 16, wherein a ring width of the second ring structure is greater than a ring width of the first ring structure.

20. The package of claim 16, further comprising:
a surface mount device over the substrate, wherein the second ring structure at least partially overlaps the surface mount device, and the first ring structure does not overlap the surface mount device.
